(19) United States
(12) Patent Application Publication
(10) Pub. No.: US 2011/0097487 A1
(43) Pub. Date: Apr. 28, 2011

(54) FLUID DISTRIBUTION MANIFOLD INCLUDING BONDED PLATES

(76) Inventors: Roger S. Kerr, Brockport, NY (US); David H. Levy, Rochester, NY (US)

(21) Appl. No.: 12/606,212

(22) Filed: Oct. 27, 2009

(51) Int. Cl. C23C 16/44; C23C 16/00; B32B 37/12

(52) U.S. Cl. 427/248.1; 137/561 R; 156/60

(57) ABSTRACT

A fluid distribution manifold includes a first plate and a second plate. At least a portion of at least the first plate and the second plate define a relief pattern. A metal bonding agent is disposed between the first plate and the second plate such that the first plate and the second plate form a fluid flow directing pattern defined by the relief pattern.

### CROSS REFERENCE TO RELATED APPLICATIONS

Reference is made to commonly-assigned, U.S. patent application Ser. No. ______ (Docket 95868), entitled “FLUID DISTRIBUTION MANIFOLD INCLUDING MIRRORED FINISH PLATE”, Ser. No. ______ (Docket 95869), entitled “DISTRIBUTION MANIFOLD INCLUDING MULTIPLE FLUID COMMUNICATION PORTS”, Ser. No. ______ (Docket 95870), entitled “FLUID DISTRIBUTION MANIFOLD INCLUDING NON-PARALLEL NON-PERPENDICULAR SLOTS”, Ser. No. ______ (Docket 95871), entitled “FLUID DISTRIBUTION MANIFOLD INCLUDING COMPLIANT PLATES”, Ser. No. ______ (Docket 95872), entitled “FLUID CONVEYANCE SYSTEM INCLUDING FLEXIBLE RETAINING MECHANISM”, Ser. No. ______ (Docket 95873), entitled “CONVEYANCE SYSTEM INCLUDING OPPOSED FLUID DISTRIBUTION MANIFOLDS” Ser. No. ______ (Docket 95874), entitled “FLUID DISTRIBUTION MANIFOLD OPERATING STATE MANAGEMENT SYSTEM”, all filed concurrently herewith.

### FIELD OF THE INVENTION

This invention generally relates diffusing flow of a gaseous or liquid material, especially during the deposition of thin-film materials and, more particularly, to apparatus for atomic layer deposition onto a substrate using a distribution or delivery head directing simultaneous gas flows onto the substrate.

### BACKGROUND OF THE INVENTION

Among the techniques widely used for thin-film deposition is Chemical Vapor Deposition (CVD) that uses chemically reactive molecules that react in a reaction chamber to deposit a desired film on a substrate. Molecular precursors useful for CVD applications comprise elemental (atomic) constituents of the film to be deposited and typically also include additional elements. CVD precursors are volatile molecules that are delivered, in a gaseous phase, to a chamber in order to react at the substrate, forming the thin film thereon. The chemical reaction deposits a thin film with a desired film thickness.

Common to most CVD techniques is the need for application of a well-controlled flux of one or more molecular precursors into the CVD reactor. A substrate is kept at a well-controlled temperature under controlled pressure conditions to promote chemical reaction between these molecular precursors, concurrent with efficient removal of byproducts. Obtaining optimum CVD performance requires the ability to achieve and sustain steady-state conditions of gas flow, temperature, and pressure throughout the process, and the ability to minimize or eliminate transients.

Especially in the field of semiconductor, integrated circuit, and other electronic devices, there is a demand for thin films, especially higher quality, denser films, with superior conformal coating properties, beyond the achievable limits of conventional CVD techniques, especially thin films that can be manufactured at lower temperatures.

Atomic layer deposition (“ALD”) is an alternative film deposition technology that can provide improved thickness resolution and conformal capabilities, compared to its CVD predecessor. The ALD process segments the conventional thin-film deposition process of conventional CVD into single atomic-layer deposition steps. Advantageously, ALD steps are self-terminating and can deposit one atomic layer when conducted up to or beyond self-termination exposure times. An atomic layer typically ranges from about 0.1 to about 0.5 molecular monolayers, with typical dimensions on the order of no more than a few Angstroms. In ALD, deposition of an atomic layer is the outcome of a chemical reaction between a reactive molecular precursor and the substrate. In each separate ALD reaction-deposition step, the net reaction deposits the desired atomic layer and substantially eliminates “extra” atoms originally included in the molecular precursor. In its most pure form, ALD involves the adsorption and reaction of each of the precursors in the absence of the other precursor or precursors of the reaction. In practice, in any system it is difficult to avoid some direct reaction of the different precursors leading to a small amount of chemical vapor deposition reaction. The goal of any system claiming to perform ALD is to obtain device performance and attributes commensurate with an ALD system while recognizing that a small amount of CVD reaction can be tolerated.

In ALD applications, typically two molecular precursors are introduced into the ALD reactor in separate stages. For example, a metal precursor molecule, MLₓ, comprises a metal element, M that is bonded to an atomic or molecular ligand, L. For example, M could be, but would not be restricted to, Al, W, Ta, Si, Zn, etc. The metal precursor reacts with the substrate when the substrate surface is prepared to react directly with the molecular precursor. For example, the substrate surface typically is prepared to include hydrogen-containing ligands, AH or the like, that are reactive with the metal precursor. Sulfur (S), oxygen (O), and Nitrogen (N) are some typical A species. The gaseous metal precursor molecule effectively reacts with all of the ligands on the substrate surface, resulting in deposition of a single atomic layer of the metal:

substrate−AH+MLₓ→substrate−AMLₓ₋₁+HL (1)

where HL is a reaction by-product. During the reaction, the initial surface ligands, AH, are consumed, and the surface becomes covered with L ligands, which cannot further react with metal precursor MLₓ. Therefore, the reaction self-terminates when all of the initial AH ligands on the surface are replaced with AMLₓ₋₁ species. The reaction stage is typically followed by an inert-gas purge stage that eliminates the excess metal precursor from the chamber prior to the separate introduction of a second reactant gaseous precursor material.

The second molecular precursor then is used to restore the surface reactivity of the substrate towards the metal precursor. This is done, for example, by removing the L ligands and redepositing AH ligands. In this case, the second precursor typically comprises the desired (usually nonmetallic) element A (i.e., O, N, S), and hydrogen (i.e., H₂O, NH₃, H₂S). The next reaction is as follows:

substrate−A−ML+AH_{Y}→substrate−A−M−AH+HL (2)

This converts the surface back to its AH-covered state. (Here, for the sake of simplicity, the chemical reactions are not balanced.) The desired additional element, A, is incorporated into the film and the undesired ligands, L, are eliminated as volatile by-products. Once again, the reaction consumes the reactive sites (this time, the L terminated sites) and self-terminates when the reactive sites on the substrate are entirely depleted. The second molecular precursor then is removed from the deposition chamber by flowing inert purge-gas in a second purge stage.

In summary, then, the basic ALD process requires alternating, in sequence, the flux of chemicals to the substrate. The representative ALD process, as discussed above, is a cycle having four different operational stages:

1. MLₓ reaction; 2. MLₓ purge; 3. AH_{y} reaction; and 4. AH_{y} purge, and then back to stage 1.

This repeated sequence of alternating surface reactions and precursor-removal that restores the substrate surface to its initial reactive state, with intervening purge operations, is a typical ALD deposition cycle. A key feature of ALD operation is the restoration of the substrate to its initial surface chemistry condition. Using this repeated set of steps, a film can be layered onto the substrate in equal metered layers that are all alike in chemical kinetics, deposition per cycle, composition, and thickness.

ALD can be used as a fabrication step for forming a number of types of thin-film electronic devices, including semiconductor devices and supporting electronic components such as resistors and capacitors, insulators, bus lines, and other conductive structures. ALD is particularly suited for forming thin layers of metal oxides in the components of electronic devices. General classes of functional materials that can be deposited with ALD include conductors, dielectrics or insulators, and semiconductors.

Conductors can be any useful conductive material. For example, the conductors may comprise transparent materials such as indium-tin oxide (ITO), doped zinc oxide ZnO, SnO₂, or In₂O₃. The thickness of the conductor may vary, and according to particular examples it can range from about 50 to about 1000 nm.

Examples of useful semiconducting materials are compound semiconductors such as gallium arsenide, gallium nitride, cadmium sulfide, intrinsic zinc oxide, and zinc sulfide.

A dielectric material electrically insulates various portions of a patterned circuit. A dielectric layer may also be referred to as an insulator or insulating layer. Specific examples of materials useful as dielectrics include strontiates, tantalates, titanates, zirconates, aluminum oxides, silicon oxides, tantalum oxides, hafnium oxides, titanium oxides, zinc selenide, and zinc sulfide. In addition, alloys, combinations, and multilayers of these examples can be used as dielectrics. Of these materials, aluminum oxides are preferred.

A dielectric structure layer may comprise two or more layers having different dielectric constants. Such insulators are discussed in U.S. Pat. No. 5,981,970 hereby incorporated by reference and copending US Publication No. 2006/0214154, hereby incorporated by reference. Dielectric materials typically exhibit a band-gap of greater than about 5 eV. The thickness of a useful dielectric layer may vary, and according to particular examples it can range from about 10 to about 300 nm.

A number of device structures can be made with the functional layers described above. A resistor can be fabricated by selecting a conducting material with moderate to poor conductivity. A capacitor can be made by placing a dielectric between two conductors. A diode can be made by placing two semiconductors of complementary carrier type between two conducting electrodes. There may also be disposed between the semiconductors of complementary carrier type a semiconductor region that is intrinsic, indicating that that region has low numbers of free charge carriers. A diode may also be constructed by placing a single semiconductor between two conductors, where one of the conductor/semiconductors interfaces produces a Schottky barrier that impedes current flow strongly in one direction. A transistor may be made by placing upon a conductor (the gate) an insulating layer followed by a semiconducting layer. If two or more additional conductor electrodes (source and drain) are placed spaced apart in contact with the top semiconductor layer, a transistor can be formed. Any of the above devices can be created in various configurations as long as the necessary interfaces are created.

In typical applications of a thin film transistor, the need is for a switch that can control the flow of current through the device. As such, it is desired that when the switch is turned on, a high current can flow through the device. The extent of current flow is related to the semiconductor charge carrier mobility. When the device is turned off, it is desirable that the current flow be very small. This is related to the charge carrier concentration. Furthermore, it is generally preferable that visible light have little or no influence on thin-film transistor response. In order for this to be true, the semiconductor band gap must be sufficiently large (>3 eV) so that exposure to visible light does not cause an inter-band transition. A material that is capable of yielding a high mobility, low carrier concentration, and high band gap is ZnO. Furthermore, for high-volume manufacture onto a moving web, it is highly desirable that chemistries used in the process are both inexpensive and of low toxicity, which can be satisfied by the use of ZnO and the majority of its precursors.

Barrier layers represent another application for which the ALD deposition process is well suited. Barrier layers are, typically, thin layers of a material that reduces, delays or even prevents the passage of a contaminant to another material. Typical contaminants include air, oxygen, and water. While barrier layers can include any material that reduces, delays or prevents the passage of the contaminant, materials that are particularly well suited for this application include insulators such as aluminum oxide and layered structures including a variety of oxides.

Self-saturating surface reactions make ALD relatively insensitive to transport non-uniformities, which might otherwise impair surface uniformity, due to engineering tolerances and the limitations of the flow system or related to surface topography (that is, deposition into three dimensional, high aspect ratio structures). As a general rule, a non-uniform flux of chemicals in a reactive process generally results in different completion times over different portions of the surface area. However, with ALD, each of the reactions is allowed to complete on the entire substrate surface. Thus, differences in completion kinetics impose no penalty on uniformity. This is because the areas that are first to complete the reaction self-terminate the reaction; other areas are able to continue until the full treated surface undergoes the intended reaction.

Typically, an ALD process deposits about 0.1-0.2 nm of a film in a single ALD cycle (with one cycle having numbered steps 1 through 4 as listed earlier). A useful and economically feasible cycle time must be achieved in order to provide a uniform film thickness in a range of from about 3 nm to 30 nm for many or most semiconductor applications, and even thicker films for other applications. According to industry throughput standards, substrates are preferably processed within 2 minutes to 3 minutes, which means that ALD cycle times must be in a range from about 0.6 seconds to about 6 seconds.

ALD offers considerable promise for providing a controlled level of highly uniform thin film deposition. However, in spite of its inherent technical capabilities and advantages, a number of technical hurdles still remain. One important consideration relates to the number of cycles needed. Because of its repeated reactant and purge cycles, effective use of ALD has required an apparatus that is capable of abruptly changing the flux of chemicals from MLₓ to AH_{y}, along with quickly performing purge cycles. Conventional ALD systems are designed to rapidly cycle the different gaseous substances onto the substrate in the needed sequence. However, it is difficult to obtain a reliable scheme for introducing the needed series of gaseous formulations into a chamber at the needed speeds and without some unwanted mixing. Furthermore, an ALD apparatus must be able to execute this rapid sequencing efficiently and reliably for many cycles in order to allow cost-effective coating of many substrates.

In an effort to minimize the time that an ALD reaction needs to reach self-termination, at any given reaction temperature, one approach has been to maximize the flux of chemicals flowing into the ALD reactor, using so-called “pulsing” systems. In order to maximize the flux of chemicals into the ALD reactor, it is advantageous to introduce the molecular precursors into the ALD reactor with minimum dilution of inert gas and at high pressures. However, these measures work against the need to achieve short cycle times and the rapid removal of these molecular precursors from the ALD reactor. Rapid removal in turn dictates that gas residence time in the ALD reactor be minimized. Gas residence times, τ, are proportional to the volume of the reactor, V, the pressure, P, in the ALD reactor, and the inverse of the flow, Q, that is:

τ=VP/Q (3)

In a typical ALD chamber the volume (V) and pressure (P) are dictated independently by the mechanical and pumping constraints, leading to difficulty in precisely controlling the residence time to low values. Accordingly, lowering pressure (P) in the ALD reactor facilitates low gas residence times and increases the speed of removal (purge) of chemical precursor from the ALD reactor. In contrast, minimizing the ALD reaction time requires maximizing the flux of chemical precursors into the ALD reactor through the use of a high pressure within the ALD reactor. In addition, both gas residence time and chemical usage efficiency are inversely proportional to the flow. Thus, while lowering flow can increase efficiency, it also increases gas residence time.

Existing ALD approaches have been compromised with the trade-off between the need to shorten reaction times with improved chemical utilization efficiency, and, on the other hand, the need to minimize purge-gas residence and chemical removal times. One approach to overcome the inherent limitations of “pulsed” delivery of gaseous material is to provide each reactant gas continuously and to move the substrate through each gas in succession. For example, U.S. Pat. No. 6,821,563 entitled “GAS DISTRIBUTION SYSTEM FOR CYCLICAL LAYER DEPOSITION” issued to Yudovsky, describes a processing chamber, under vacuum, having separate gas ports for precursor and purge gases, alternating with vacuum pump ports between each gas port. Each gas port directs its stream of gas vertically downward toward a substrate. The separate gas flows are separated by walls or partitions, with vacuum pumps for evacuating gas on both sides of each gas stream. A lower portion of each partition extends close to the substrate, for example, about 0.5 mm or greater from the substrate surface. In this manner, the lower portions of the partitions are separated from the substrate surface by a distance sufficient to allow the gas streams to flow around the lower portions toward the vacuum ports after the gas streams react with the substrate surface.

A rotary turntable or other transport device is provided for holding one or more substrate wafers. With this arrangement, the substrate is shuttled beneath the different gas streams, effecting ALD deposition thereby. In one embodiment, the substrate is moved in a linear path through a chamber, in which the substrate is passed back and forth a number of times.

Another approach using continuous gas flow is shown in U.S. Pat. No. 4,413,022 entitled “METHOD FOR PERFORMING GROWTH OF COMPOUND THIN FILMS” issued to Suntola et al. A gas flow array is provided with alternating source gas openings, carrier gas openings, and vacuum exhaust openings. Reciprocating motion of the substrate over the array effects ALD deposition, again, without the need for pulsed operation. In the embodiment of FIGS. 13 and 14, in particular, sequential interactions between a substrate surface and reactive vapors are made by a reciprocating motion of the substrate over a fixed array of source openings. Diffusion barriers are formed by having a carrier gas opening between exhaust openings. Suntola et al. state that operation with such an embodiment is possible even at atmospheric pressure, although little or no details of the process, or examples, are provided.

While systems such as those described in the '563 Yudovsky and '022 Suntola et al. patents may avoid some of the difficulties inherent to pulsed gas approaches, these systems have other drawbacks. Neither the gas flow delivery unit of the '563 Yudovsky patent nor the gas flow array of the '022 Suntola et al. patent can be used in closer proximity to the substrate than about 0.5 mm. Neither of the gas flow delivery apparatus disclosed in the '563 Yudovsky and '022 Suntola et al. patents are arranged for possible use with a moving web surface, such as could be used as a flexible substrate for forming electronic circuits, light sensors, or displays, for example. The complex arrangements of both the gas flow delivery unit of the '563 Yudovsky patent and the gas flow array of the '022 Suntola et al. patent, each providing both gas flow and vacuum, make these solutions difficult to implement, costly to scale, and limit their potential usability to deposition applications onto a moving substrate of limited dimensions. Moreover, it would be very difficult to maintain a uniform vacuum at different points in an array and to maintain synchronous gas flow and vacuum at complementary pressures, thus compromising the uniformity of gas flux that is provided to the substrate surface.

US Patent Application Publication No. US 2005/0084610 by Selitser discloses an atmospheric pressure atomic layer chemical vapor deposition process. Selitser state that extraordinary increases in reaction rates are obtained by changing the operating pressure to atmospheric pressure, which will involve orders of magnitude increase in the concentration of reactants, with consequent enhancement of surface reactant rates. The embodiments of Selitser involve separate chambers for each stage of the process, although FIG. 10 in US Patent Application Publication No. US 2005/0084610 shows an embodiment in which chamber walls are removed. A series of separated injectors are spaced around a rotating circular substrate holder track. Each injector incorporates independently operated reactant, purging, and exhaust gas manifolds and controls and acts as one complete mono-layer deposition and reactant purge cycle for each substrate as is passes there under in the process. Little or no specific details of the gas injectors or manifolds are described by Selitser, although they state that spacing of the injectors is selected so that cross-contamination from adjacent injectors is prevented by purging gas flows and exhaust manifolds incorporated in each injector.

A particularly useful method to provide for the isolation of mutually reactive ALD gases is the gas bearing ALD device described in US Patent Application Publication No. US 2008/0166880, published Jul. 10, 2008, by Levy. The efficiency of this device arises from the fact that relatively high pressures are generated in the gap between the deposition head and the substrate, which force gases in a well-defined path from a source area to an exhaust region while in proximity to the substrate experiencing deposition.

As ALD deposition processes are suitable for use in various industries for a variety of applications, there is an ongoing effort to improve ALD deposition processes, systems, and devices, particularly in an area of ALD commonly referred to as spatially dependent ALD.

### SUMMARY OF THE INVENTION

According to one aspect of the invention, a fluid distribution manifold includes a first plate and a second plate. At least a portion of at least the first plate and the second plate define a relief pattern. A metal bonding agent is disposed between the first plate and the second plate such that the first plate and the second plate form a fluid flow directing pattern defined by the relief pattern.

According to another aspect of the invention, a method of assembling a fluid distribution head includes providing a first plate; providing a second plate, at least a portion of at least the first plate and the second plate defining a relief pattern; providing a metal bonding agent disposed between the first plate and the second plate; and forming a fluid flow directing pattern defined by the relief pattern by bonding the first plate and the second plate together using the metal bonding agent.

According to another aspect of the invention, a method of depositing a thin film material on a substrate includes providing a substrate; providing a fluid distribution manifold including: a first plate; a second plate, at least a portion of at least the first plate and the second plate defining a relief pattern; and a metal bonding agent disposed between the first plate and the second plate such that the first plate and the second plate form a fluid flow directing pattern defined by the relief pattern; and causing a gaseous material to flow from the fluid distribution manifold toward the substrate after causing the gaseous material to flow through the fluid flow directing pattern defined by the relief pattern.

### BRIEF DESCRIPTION OF THE DRAWINGS

In the detailed description of the example embodiments of the invention presented below, reference is made to the accompanying drawings, in which:

FIGS. 1A through 1D show diagrammatic depictions of the assembly of plates containing relief patterns to form micro-channel diffusing elements;

FIG. 2 shows several exemplary diffuser relief patterns and the possibility for a variable relief pattern;

FIG. 3 is a cross-sectional side view of one embodiment of a delivery device for atomic layer deposition according to the present invention;

FIG. 4 is a cross-sectional side view of one embodiment of a delivery device showing one exemplary arrangement of gaseous materials provided to a substrate that is subject to thin film deposition;

FIGS. 5A and 5B are cross-sectional side views of one embodiment of a delivery device, schematically showing the accompanying deposition operation;

FIG. 6 is a perspective exploded view of a delivery device in a deposition system according to one embodiment, including an optional diffuser unit;

FIG. 7A is a perspective view of a connection plate for the delivery device of FIG. 6;

FIG. 7B is a plan view of a gas chamber plate for the delivery device of FIG. 6;

FIG. 7C is a plan view of a gas direction plate for the delivery device of FIG. 6;

FIG. 7D is a plan view of a base plate for the delivery device of FIG. 6;

FIG. 8 is a perspective view of the supply portions of one embodiment of a delivery device machined from a single piece of material, onto which a diffuser element of this invention could be directly attached;

FIG. 9 is a perspective view showing a two plate diffuser assembly for a delivery device in one embodiment;

FIGS. 10A and 10B show a plan view and a perspective cross-section view of one of the two plates in one embodiment of a horizontal plate diffuser assembly;

FIGS. 11A and 11B show the plan view and a perspective cross-section view of the other plate with respect to FIG. 9 in a horizontal plate diffuser assembly;

FIGS. 12A and 12B show a cross-section view and a magnified cross-sectional view respectively of an assembled two plate diffuser assembly;

FIG. 13 is a perspective exploded view of a delivery device in a deposition system according to one embodiment employing plates perpendicular to the resulting output face;

FIG. 14 shows a plan view of a spacer plate containing no relief patterns for use in a perpendicular plate orientation design;

FIGS. 15A through 15C show plan, perspective, and perspective sectioned views, respectively, of a source plate containing relief patterns for use in a perpendicular plate orientation design;

FIGS. 16A through 16C show plan, perspective, and perspective sectioned views, respectively, of a source plate containing a coarse relief pattern for use in a perpendicular plate orientation design;

FIGS. 17A and 17B show a relief containing plate with sealing plates that contain a deflection in order to prevent gas that exits for diffuser from impinging directly on the substrate;

FIG. 18 shows a flow diagram for a method of assembling the delivery devices of this invention;

FIG. 19 is a side view of a delivery head showing relevant distance dimensions and force directions;

FIG. 20 is a perspective view showing a distribution head used with a substrate transport system;

FIG. 21 is a perspective view showing a deposition system using the delivery head of the present invention;

FIG. 22 is a perspective view showing one embodiment of a deposition system applied to a moving web;

FIG. 23 is a perspective view showing another embodiment of deposition system applied to a moving web;

FIG. 24 is a cross-sectional side view of one embodiment of a delivery head with an output face having curvature;

FIG. 25 is a perspective view of an embodiment using a gas cushion to separate the delivery head from the substrate;

FIG. 26 is a side view showing an embodiment for a deposition system comprising a gas fluid bearing for use with a moving substrate;

FIG. 27 is an exploded view of a gas diffuser unit according to one embodiment;

FIG. 28A is a plan view of a nozzle plate of the gas diffuser unit of FIG. 27;

FIG. 28B is a plan view of a gas diffuser plate of the gas diffuser unit of FIG. 27;

FIG. 28C is a plan view of a face plate of the gas diffuser unit of FIG. 27;

FIG. 28D is a perspective view of gas mixing within the gas diffuser unit of FIG. 27;

FIG. 28E is a perspective view of the gas ventilation path using the gas diffuser unit of FIG. 27;

FIG. 29A is a perspective cross-sectional view of an assembled two plate diffuser assembly;

FIG. 29B is a perspective cross-sectional view of an assembled two plate diffuser assembly;

FIG. 29C is a perspective cross-sectional view of an assembled two plate gaseous fluid flow channel;

FIG. 30 is a is a perspective cross-sectional exploded view of an assembled two plate diffuser assembly showing one or more locations where a mirrored surface finish can be present;

FIGS. 31A-31C are cross-sectional views a fluid distribution manifold including a primary chamber connected in fluid communication to a secondary fluid source;

FIG. 32A-32D are schematic top views of example embodiments of output faces of a fluid distribution manifold showing source slot and exhaust slot configurations;

FIGS. 33A-33C are schematic side views of an example embodiment of a fluid distribution manifold that includes an output face that is not flat;

FIG. 34 is a schematic side view of an example embodiment of a fluid conveyance system that provides force to two sides of a substrate being coated;

FIG. 35 is a perspective view of an example embodiment of a fluid conveyance system including gas parameter sensing capabilities made in accordance with the present invention;

FIG. 36 is a schematic side view of an example embodiment of a fluid conveyance system that includes a fixed substrate transport subsystem;

FIG. 37 is a schematic side view of an example embodiment of a fluid conveyance system that includes a moveable substrate transport subsystem; and

FIG. 38 is a schematic side view of an example embodiment of a fluid conveyance system that includes a substrate transport subsystem having a non-planer contour.

### DETAILED DESCRIPTION OF THE INVENTION

The present description will be directed in particular to elements forming part of, or cooperating more directly with, apparatus in accordance with the present invention. It is to be understood that elements not specifically shown or described can take various forms well known to those skilled in the art. In the following description and drawings, identical reference numerals have been used, where possible, to designate identical elements.

The example embodiments of the present invention are illustrated schematically and not to scale for the sake of clarity. The figures provided are intended to show overall function and the structural arrangement of the example embodiments of the present invention. One of the ordinary skills in the art will be able to readily determine the specific size and interconnections of the elements of the example embodiments of the present invention.

For the description that follows, the term “gas” or “gaseous material” is used in a broad sense to encompass any of a range of vaporized or gaseous elements, compounds, or materials. Other terms used herein, such as: reactant, precursor, vacuum, and inert gas, for example, all have their conventional meanings as would be well understood by those skilled in the materials deposition art. Superposition has its conventional meaning, wherein elements are laid atop or against one another in such manner that parts of one element align with corresponding parts of another and that their perimeters generally coincide. The terms “upstream” and “downstream” have their conventional meanings as relates to the direction of gas flow.

The present invention is particularly applicable to a form of ALD, commonly referred to as spatially dependent ALD, employing an improved distribution device for delivery of gaseous materials to a substrate surface, adaptable to deposition on larger and web-based substrates and capable of achieving a highly uniform thin-film deposition at improved throughput speeds. The apparatus and method of the present invention employs a continuous (as opposed to pulsed) gaseous material distribution. The apparatus of the present invention allows operation at atmospheric or near-atmospheric pressures as well as under vacuum and is capable of operating in an unsealed or open-air environment.

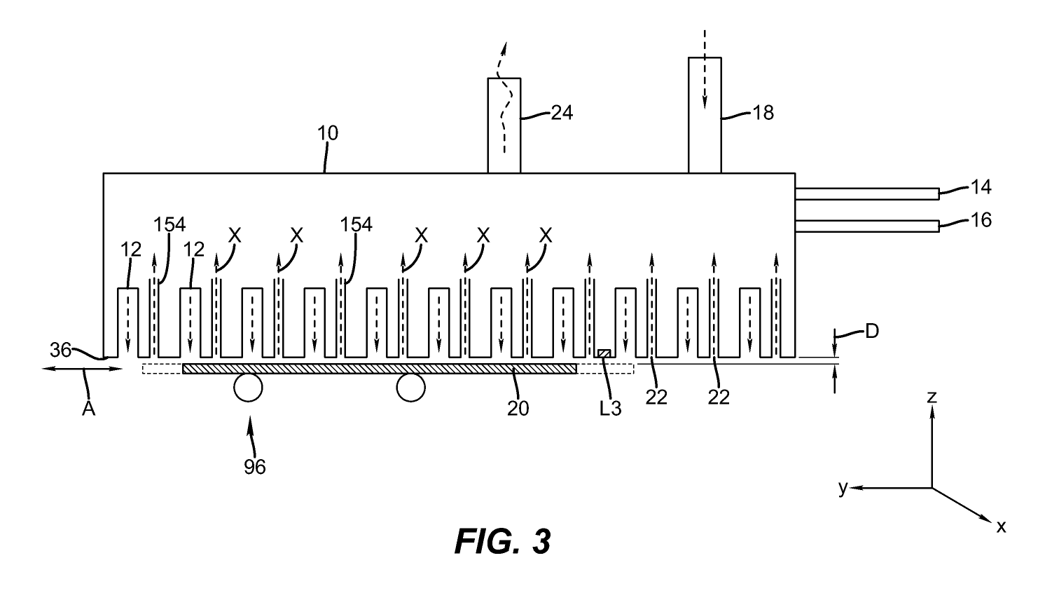

Referring to FIG. 3, there is shown a cross-sectional side view of one embodiment of a delivery head 10 for atomic layer deposition onto a substrate 20 according to the present invention. This is commonly referred to as a “floating head” design because relative separation of the delivery head and the substrate is accomplished and maintained using the gas pressure generated by the flow of one or more gases from the delivery head to the substrate. This type of delivery head has been described in more detail in commonly assigned US Patent Application Publication No. US 2009/0130858 A1, published May 21, 2009, by Levy.

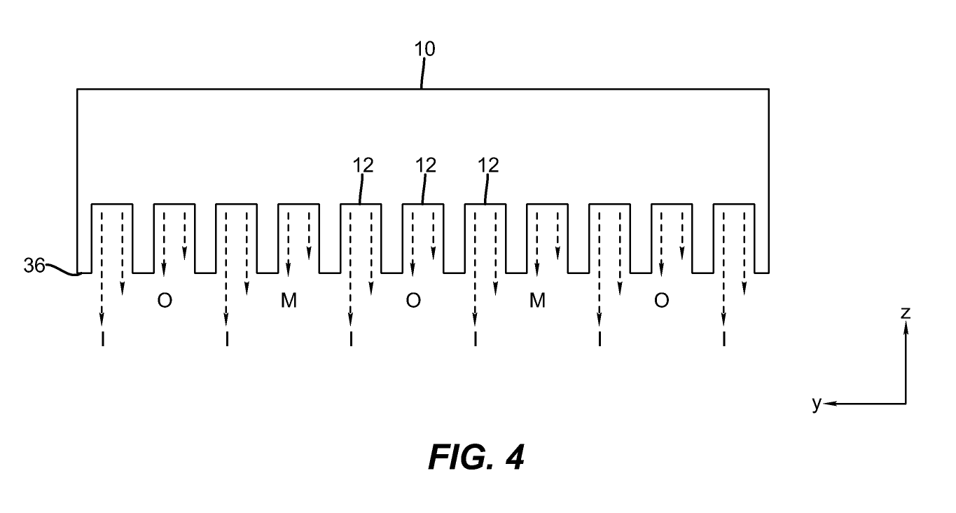

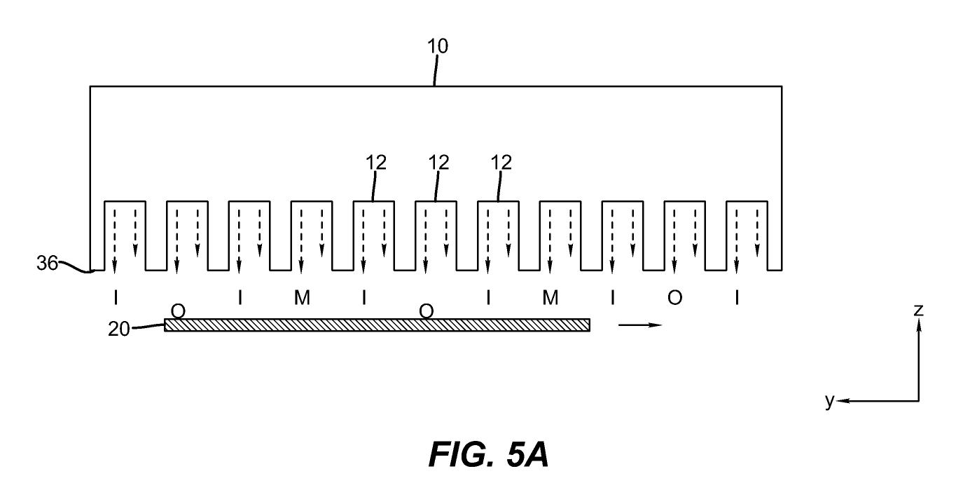

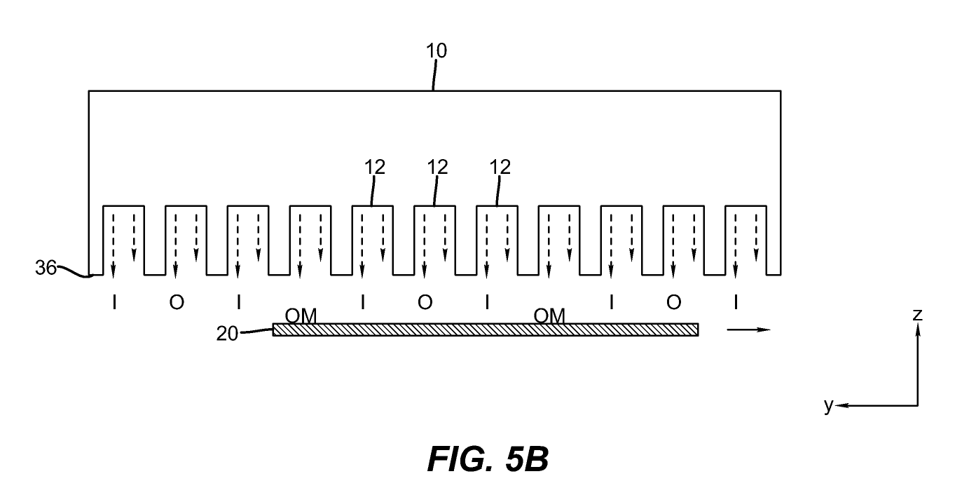

Delivery head 10 has a gas inlet port connected to conduit 14 for accepting a first gaseous material, a gas inlet port connected to conduit 16 for accepting a second gaseous material, and a gas inlet port connected to conduit 18 for accepting a third gaseous material. These gases are emitted at an output face 36 via output channels 12, having a structural arrangement described subsequently. The dashed line arrows in FIG. 3 and subsequent FIGS. 4-5B refer to the delivery of gases to substrate 20 from delivery head 10. In FIG. 3, dotted line arrows X also indicate paths for gas exhaust (shown directed upwards in this figure) and exhaust channels 22, in communication with an exhaust port connected to conduit 24. For simplicity of description, gas exhaust is not indicated in FIGS. 4-5B. Because the exhaust gases still may contain quantities of unreacted precursors, it can be undesirable to allow an exhaust flow predominantly containing one reactive species to mix with one predominantly containing another species. As such, it is recognized that the delivery head 10 can include several independent exhaust ports.

In one embodiment, gas inlet conduits 14 and 16 are adapted to accept first and second gases that react sequentially on the substrate surface to effect ALD deposition, and gas inlet conduit 18 receives a purge gas that is inert with respect to the first and second gases. Delivery head 10 is spaced a distance D from substrate 20, which can be provided on a substrate support, as described in more detail subsequently. Reciprocating motion can be provided between substrate 20 and delivery head 10, either by movement of substrate 20, by movement of delivery head 10, or by movement of both substrate 20 and delivery head 10. In the particular embodiment shown in FIG. 3, substrate 20 is moved by a substrate support 96 across output face 36 in reciprocating fashion, as indicated by the arrow A and by phantom outlines to the right and left of substrate 20 in FIG. 3. It should be noted that reciprocating motion is not always necessary for thin-film deposition using delivery head 10. Other types of relative motion between substrate 20 and delivery head 10 can also be provided, such as movement of either substrate 20 or delivery head 10 in one or more directions, as described in more detail subsequently.

The cross-sectional view of FIG. 4 shows gas flows emitted over a portion of output face 36 of delivery head 10 (with the exhaust path omitted as noted earlier). In this particular arrangement, each output channel 12 is in gaseous flow communication with one of gas inlet conduits 14, 16 or 18 as shown in FIG. 3. Each output channel 12 delivers typically a first reactant gaseous material O, or a second reactant gaseous material M, or a third inert gaseous material I.

FIG. 4 shows a relatively basic or simple arrangement of gases. A plurality of flows of a non-metal deposition precursor (like material O) or a plurality of flows of a metal-containing precursor material (like material M) can be delivered sequentially at various ports in a thin-film single deposition. Alternately, a mixture of reactant gases, for example, a mixture of metal precursor materials or a mixture of metal and non-metal precursors can be applied at a single output channel when making complex thin film materials, for example, having alternate layers of metals or having lesser amounts of dopants admixed in a metal oxide material. Significantly, an inter-stream labeled I for an inert gas, also termed a purge gas, separates any reactant channels in which the gases are likely to react with each other. First and second reactant gaseous materials O and M react with each other to effect ALD deposition, but neither reactant gaseous material O nor M reacts with inert gaseous material I. The nomenclature used in FIG. 4 and following suggests some typical types of reactant gases. For example, first reactant gaseous material O can be an oxidizing gaseous material; second reactant gaseous material M can be a metal-containing compound, such as a material containing zinc. Inert gaseous material I can be nitrogen, argon, helium, or other gases commonly used as purge gases in ALD systems. Inert gaseous material I is inert with respect to first or second reactant gaseous materials O and M. Reaction between first and second reactant gaseous materials forms a metal oxide or other binary compound, such as zinc oxide ZnO or ZnS, used in semiconductors, in one embodiment. Reactions between more than two reactant gaseous materials can form a ternary compound, for example, ZnAlO.

The cross-sectional views of FIGS. 5A and 5B show, in simplified schematic form, the ALD coating operation performed as substrate 20 passes along output face 36 of delivery head 10 when delivering reactant gaseous materials O and M. In FIG. 5A, the surface of substrate 20 first receives an oxidizing material continuously emitted from output channels 12 designated as delivering first reactant gaseous material O. The surface of the substrate now contains a partially reacted form of material O, which is susceptible to reaction with material M. Then, as substrate 20 passes into the path of the metal compound of second reactant gaseous material M, the reaction with M takes place, forming a metallic oxide or some other thin film material that can be formed from two reactant gaseous materials. Unlike conventional solutions, the deposition sequence shown in FIGS. 5A and 5B is continuous during deposition for a given substrate or specified area thereof, rather than pulsed. That is, materials O and M are continuously emitted as substrate 20 passes across the surface of delivery head 10 or, conversely, as delivery head 10 passes along the surface of substrate 20.

As FIGS. 5A and 5B show, inert gaseous material I is provided in alternate output channels 12, between the flows of first and second reactant gaseous materials O and M. Notably, as was shown in FIG. 3, there are exhaust channels 22. Only exhaust channels 22, providing a small amount of draw, are needed to vent spent gases emitted from delivery head 10 and used in processing.

In one embodiment, as described in more detail in copending, commonly assigned US Patent Application Publication No. US 2009/0130858, gas pressure is provided against substrate 20, such that separation distance D is maintained, at least in part, by the force of pressure that is exerted. By maintaining some amount of gas pressure between output face 36 and the surface of substrate 20, the apparatus of the present invention can provide at least some portion of an air bearing, or more properly a gas fluid bearing, for delivery head 10 itself or, alternately, for substrate 20. This arrangement helps to simplify the transport mechanism for delivery head 10. The effect of allowing the delivery device to approach the substrate such that it is supported by gas pressure helps to provide isolation between the gas streams. By allowing the head to float on these streams, pressure fields are set up in the reactive and purge flow areas that cause the gases to be directed from inlet to exhaust with little or no intermixing of other gas streams. In one such embodiment, since the separation distance D is relatively small, even a small change in distance D (for example, even 100 micrometers) may necessitate a significant change in flow rates and consequently gas pressure providing the separation distance D. For example, in one embodiment, doubling the separation distance D, involving a change less than 1 mm, can necessitate more than doubling, preferably more than quadrupling, the flow rate of the gases providing the separation distance D. Alternatively, while air bearing effects can be used to at least partially separate delivery head 10 from the surface of substrate 20, the apparatus of the present invention can be used to lift or levitate substrate 20 from output surface 36 of delivery head 10.

The present invention does not require a floating head system, however, and the delivery device and the substrate can be at a fixed distance D as in conventional systems. For example, the delivery device and the substrate can be mechanically fixed at separation distance from each other in which the head is not vertically mobile in relationship to the substrate in response to changes in flow rates and in which the substrate is on a vertically fixed substrate support. Alternatively, other types of substrate holders can be used, including, for example, a platen.

In one embodiment of the invention, the delivery device has an output face for providing gaseous materials for thin-film material deposition onto a substrate. The delivery device includes a plurality of inlet ports, for example, at least a first, a second, and a third inlet port capable of receiving a common supply for a first, a second and a third gaseous material, respectively. The delivery head also includes a first plurality of elongated emissive channels, a second plurality of elongated emissive channels and a third plurality of elongated emissive channels, each of the first, second, and third elongated emissive channels allowing gaseous fluid communication with one of corresponding first, second, and third inlet ports. The delivery device is formed as a plurality of apertured plates, disposed substantially in parallel with respect to the output face, and superposed to define a network of interconnecting supply chambers and directing channels for routing each of the first, second, and third gaseous materials from its corresponding inlet port to its corresponding plurality of elongated emissive channels.

Each of the first, second, and third plurality of elongated emissive channels extend in a length direction and are substantially in parallel. Each first elongated emissive channel is separated on each elongated side thereof from the nearest second elongated emissive channel by a third elongated emissive channel. Each first elongated emissive channel and each second elongated emissive channel is situated between third elongated emissive channels.

Each of the elongated emissive channels in at least one plurality of the first, second and third plurality of elongated emissive channels is capable of directing a flow, respectively, of at least one of the first, second, and the third gaseous material substantially orthogonally with respect to the output face of the delivery device. The flow of gaseous material is capable of being provided, either directly or indirectly from each of the elongated emissive channels in the at least one plurality, substantially orthogonally to the surface of the substrate.

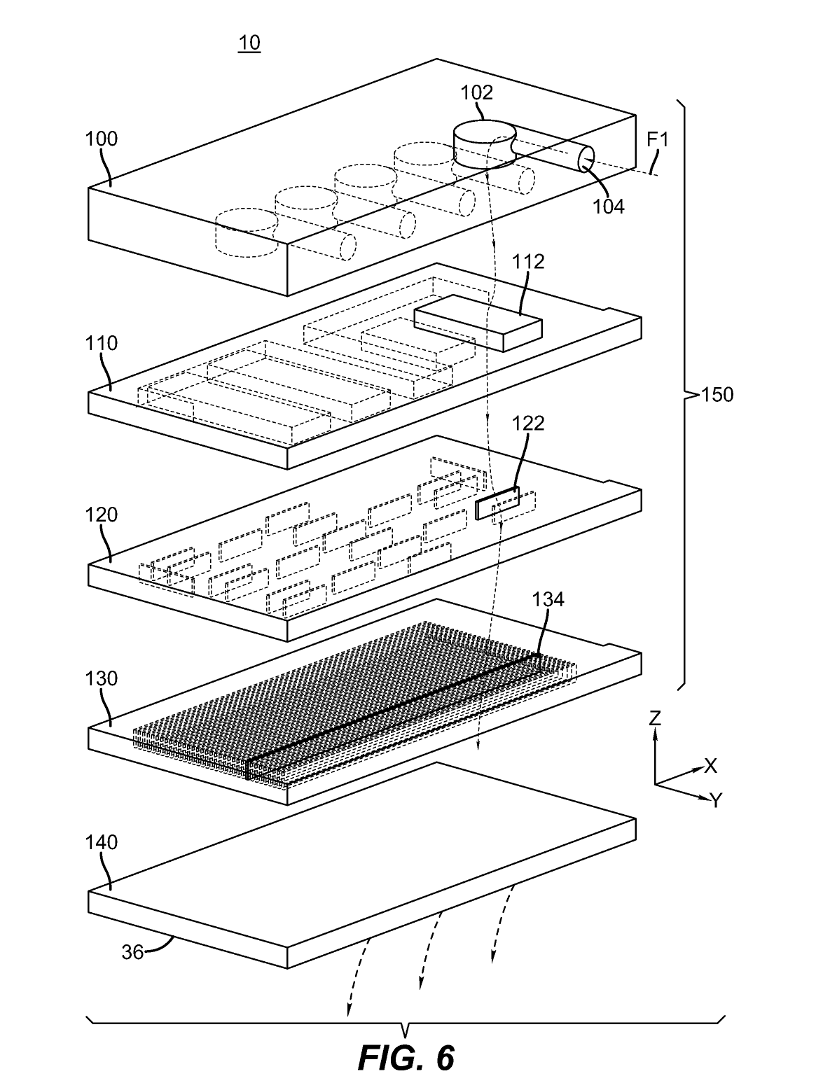

The exploded view of FIG. 6 shows, for a small portion of the overall assembly in one such embodiment, how delivery head 10 can be constructed from a set of apertured plates and shows an exemplary gas flow path for just one portion of one of the gases. A connection plate 100 for the delivery head 10 has a series of input ports 104 for connection to gas supplies that are upstream of delivery head 10 and not shown in FIG. 6. Each input port 104 is in communication with a directing chamber 102 that directs the received gas downstream to a gas chamber plate 110. Gas chamber plate 110 has a supply chamber 112 that is in gas flow communication with an individual directing channel 122 on a gas direction plate 120. From directing channel 122, the gas flow proceeds to a particular elongated exhaust channel 134 on a base plate 130. A gas diffuser unit 140 provides diffusion and final delivery of the input gas at its output face 36. A diffuser system is especially advantageous for a floating head system described above, since it can provide a back pressure within the delivery device that facilitates the floating of the head. An exemplary gas flow F1 is traced through each of the component assemblies of delivery head 10.

As shown in the example of FIG. 6, delivery assembly 150 of delivery head 10 is formed as an arrangement of superposed apertured plates: connection plate 100, gas chamber plate 110, gas direction plate 120, and base plate 130. These plates are disposed substantially in parallel to output face 36 in this “horizontal” embodiment.

Gas diffuser unit 140 is formed from superposed apertured plates, as is described subsequently. It can be appreciated that any of the plates shown in FIG. 6 can be fabricated from a stack of superposed plates. For example, it can be advantageous to form connection plate 100 from four or five stacked apertured plates that are suitably coupled together. This type of arrangement can be less complex than machining or molding methods for forming directing chambers 102 and input ports 104.

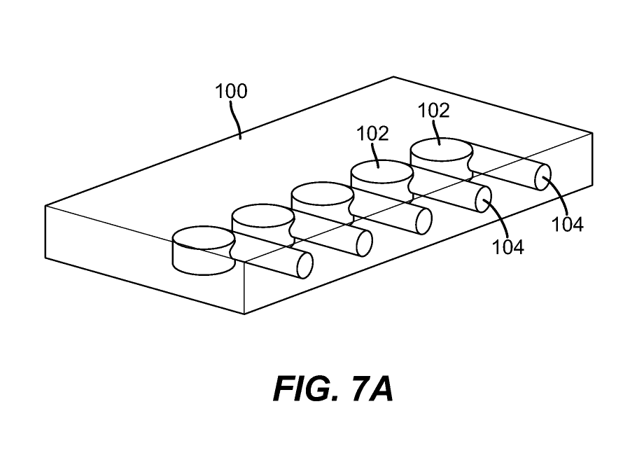

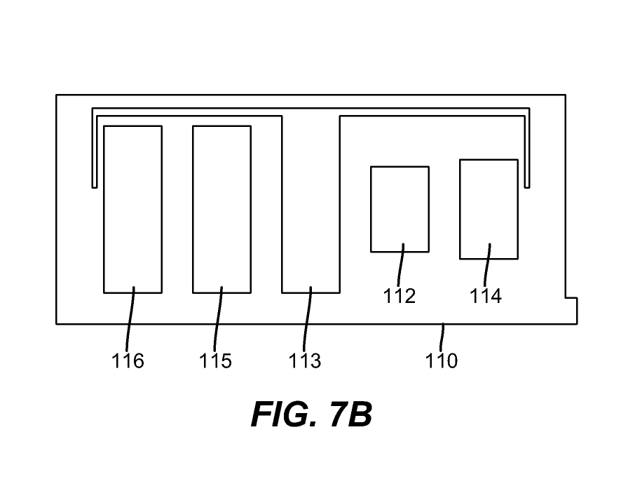

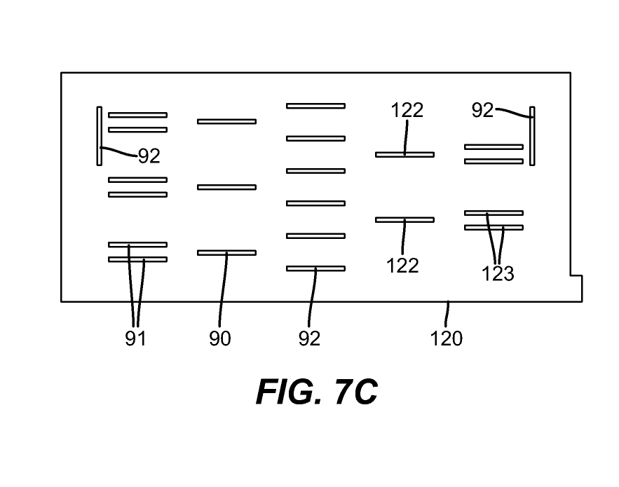

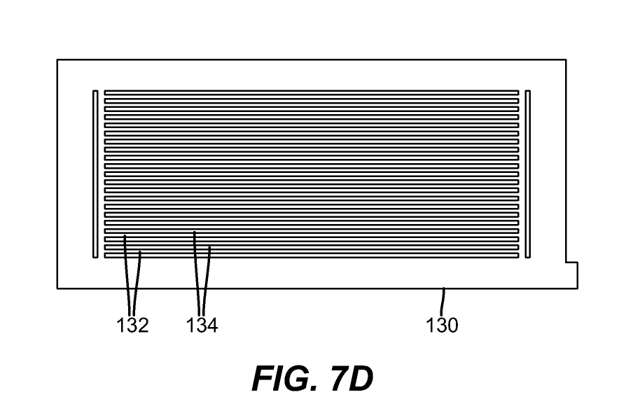

FIGS. 7A through 7D show each of the major components that can be combined together to form delivery head 10 in the embodiment of FIG. 6. FIG. 7A is a perspective view of connection plate 100, showing multiple directing chambers 102 and input ports 104. FIG. 7B is a plan view of gas chamber plate 110. A supply chamber 113 is used for purge or inert gas (involving mixing on a molecular basis between the same molecular species during steady state operation) for delivery head 10 in one embodiment. A supply chamber 115 provides mixing for a precursor gas (O) in one embodiment; an exhaust chamber 116 provides an exhaust path for this reactive gas. Similarly, a supply chamber 112 provides the other needed reactive gas, second reactant gaseous material (M); an exhaust chamber 114 provides an exhaust path for this gas.

FIG. 7C is a plan view of gas direction plate 120 for delivery head 10 in this embodiment. Multiple directing channels 122, providing a second reactant gaseous material (M), are arranged in a pattern for connecting the appropriate supply chamber 112 (not shown in this view) with base plate 130. Corresponding exhaust directing channels 123 are positioned near directing channels 122. Directing channels 90 provide the first reactant gaseous material (O). Directing channels 92 provide purge gas (I).

FIG. 7D is a plan view showing base plate 130 formed from horizontal plates. Optionally, base plate 130 can include input ports 104 (not shown in FIG. 7D). The plan view of FIG. 7D shows the external surface of base plate 130 as viewed from the output side and having elongated emissive channels 132 and elongated exhaust channels 134. With reference to FIG. 6, the view of FIG. 7D is taken from the side that faces gas diffuser unit 140. Again, it should be emphasized that FIGS. 6 and 7A-7D show one illustrative embodiment; numerous other embodiments are also possible.

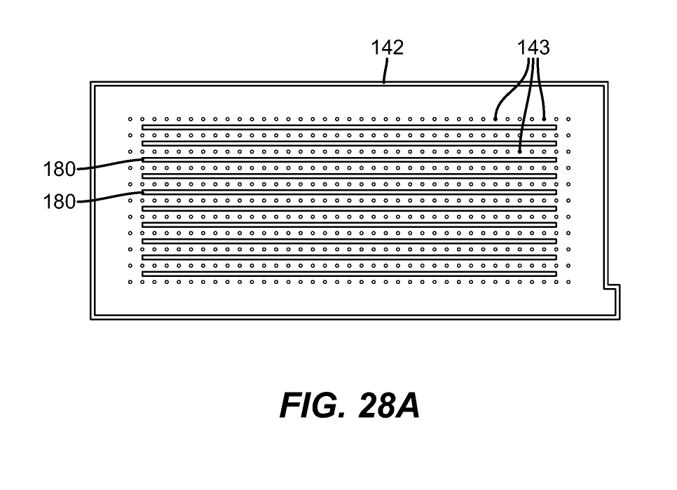

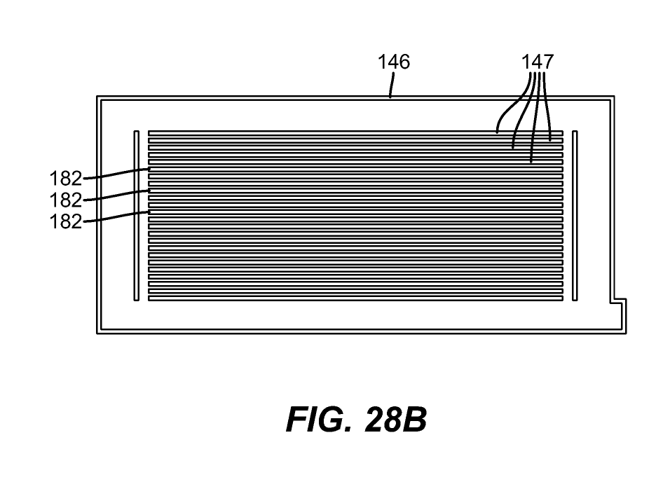

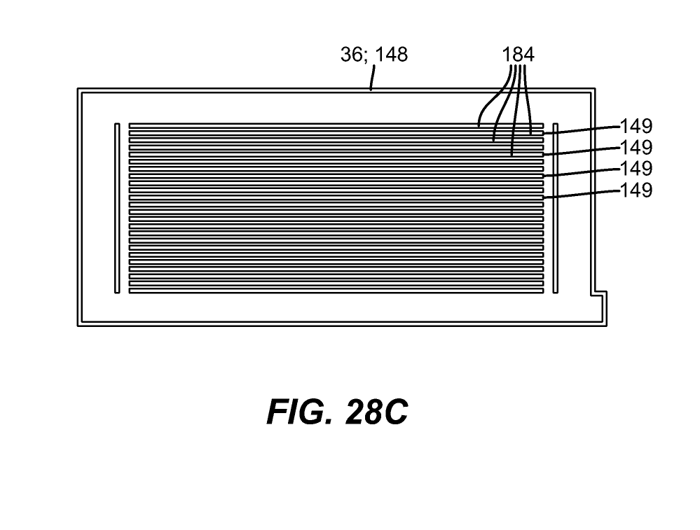

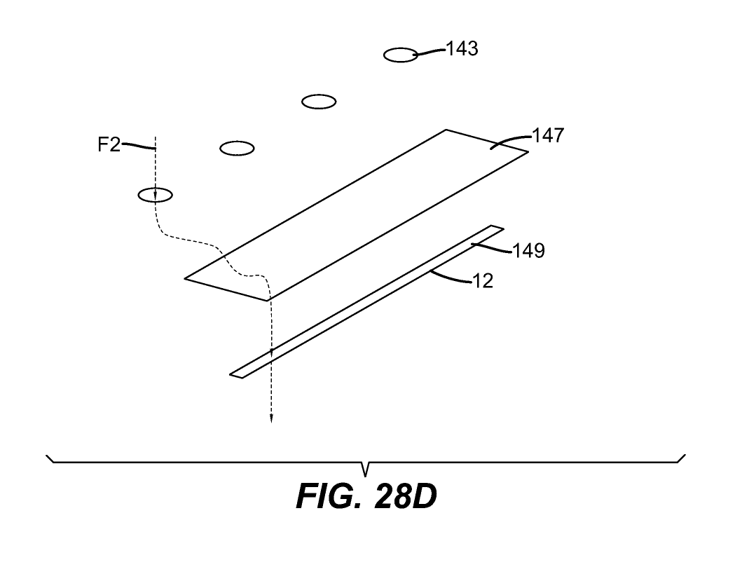

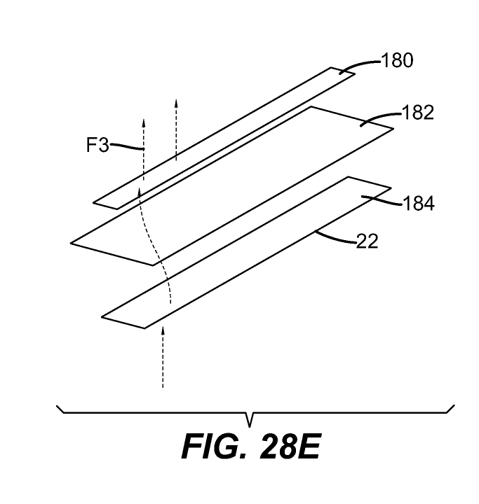

The exploded view of FIG. 27 shows the basic arrangement of components used to form one embodiment of an optional gas diffuser unit 140, as used in the embodiment of FIG. 6 and in other embodiments as described subsequently. These include a nozzle plate 142, shown in the plan view of FIG. 28A. As shown in the views of FIGS. 6, 27, and 28A, nozzle plate 142 mounts against base plate 130 and obtains its gas flows from elongated emissive channels 132. In the embodiment shown, gas conduits 143 provide the needed gaseous materials. Sequential first exhaust slots 180 are provided in the exhaust path, as described subsequently.

Referring to FIG. 28B, a gas diffuser plate 146, which diffuses in cooperation with plates 142 and 148 (shown in FIG. 27), is mounted against nozzle plate 142. The arrangement of the various passages on nozzle plate 142, gas diffuser plate 146, and output face plate 148 are optimized to provide the needed amount of diffusion for the gas flow and, at the same time, to efficiently direct exhaust gases away from the surface area of substrate 20. Slots 182 provide exhaust ports. In the embodiment shown, gas supply slots forming output passages 147 and exhaust slots 182 alternate in gas diffuser plate 146.

Output face plate 148, as shown in FIG. 28C, faces substrate 20. Output passages 149 for providing gases and exhaust slots 184 again alternate with this embodiment. Output passages 149 are commonly referred to as elongated emissive slots because they serve as the output channels 12 for delivery head 10 when diffuser unit 140 is included.

FIG. 28D focuses on the gas delivery path through gas diffuser unit 140 while FIG. 28E shows the gas exhaust path in a corresponding manner. Referring to FIG. 28D there is shown, for a representative set of gas ports, the overall arrangement used for thorough diffusion of the reactant gas for an output flow F2 in one embodiment. The gas from base plate 130 (FIG. 6) is provided through gas conduit 143 on nozzle plate 142. The gas goes downstream to an output passage 147 on gas diffuser plate 146. As shown in FIG. 28D, there can be a vertical offset (that is, using the horizontal plate arrangement shown in FIG. 27, vertical being normal with respect to the plane of the horizontal plates) between conduit 143 and passage 147 in one embodiment, helping to generate backpressure and thus facilitate a more uniform flow. The gas then goes further downstream to an output passage 149 on output face plate 148 to provide output channel 12. The conduits 143 and output passages 147 and 149 can not only be spatially offset, but can also have different geometries to optimize mixing.

In the absence of the optional diffuser unit, the elongated emissive channels 132 in the base plate can serve as the output channels 12 for delivery head 10 instead of the output passages 149. Passages 149 are commonly referred to as elongated emissive slots because they serve as the output channels 12 for delivery head 10 when diffuser unit 140 is included.

FIG. 28E symbolically traces the exhaust path provided for venting gases in a similar embodiment, where the downstream direction is opposite that for supplied gases. A flow F3 indicates the path of vented gases through sequential third, second and first exhaust slots 184, 182, and 180, respectively. Unlike the more circuitous mixing path of flow F2 for gas supply, the venting arrangement shown in FIG. 28E is intended for the rapid movement of spent gases from the surface. Thus, flow F3 is relatively direct, venting gases away from the substrate surface.

Referring back to FIG. 6, the combination of components shown as connection plate 100, gas chamber plate 110, gas direction plate 120, and base plate 130 can be grouped to provide a delivery assembly 150. Alternate embodiments are possible for delivery assembly 150, including one, described below, formed from vertical, rather than horizontal, apertured plates, using the coordinate arrangement and view of FIG. 6.

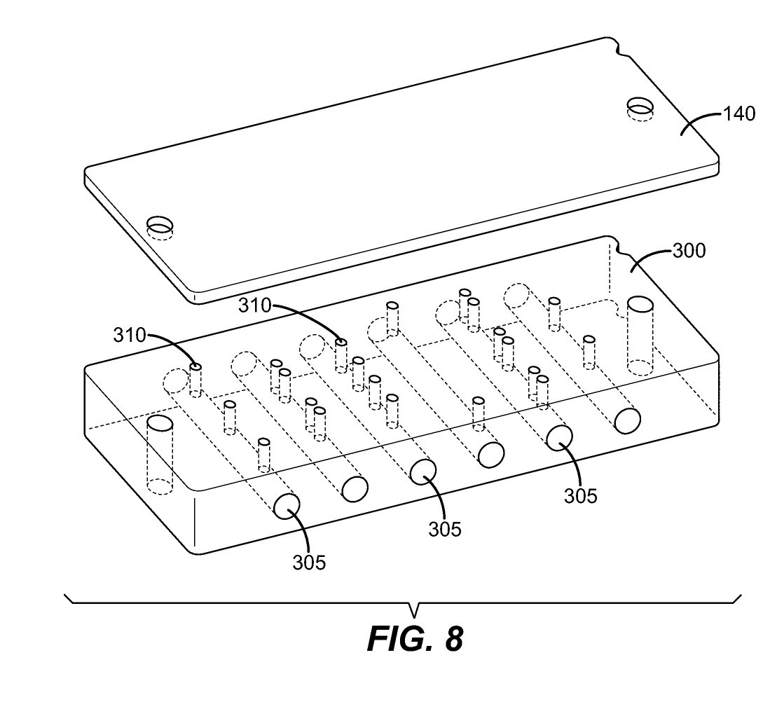

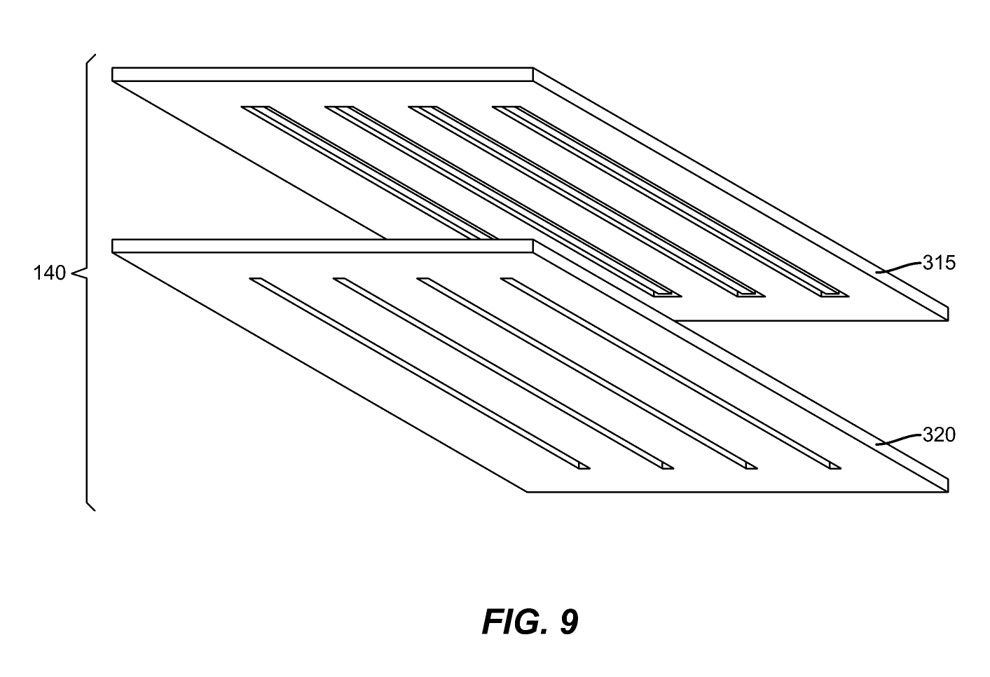

The elements of the delivery head of the embodiment of FIG. 6 are composed of several overlying plates in order to achieve the necessary gas flow paths to deliver gases in the correct locations to the diffusers. This method is useful because very complicated internal pathways can be produced by a simple superposition of apertured plates. Alternatively, it is possible with current machining or rapid prototyping methods to machine a single block of materials to contain adequate internal pathways to interface with the diffusers. For example, FIG. 8 shows an embodiment of a single machined block 300. In this block, supply lines 305 are formed by boring channels through the block. These lines can exit on both ends as shown or be capped or sealed on one end. In operation, these channels can be fed by both ends or serve as feed troughs to subsequent blocks mounted in a total system. From these supply lines, small channels 310 extend to the diffuser plate assembly 140 in order to feed the various channels leading the elongated output face openings.

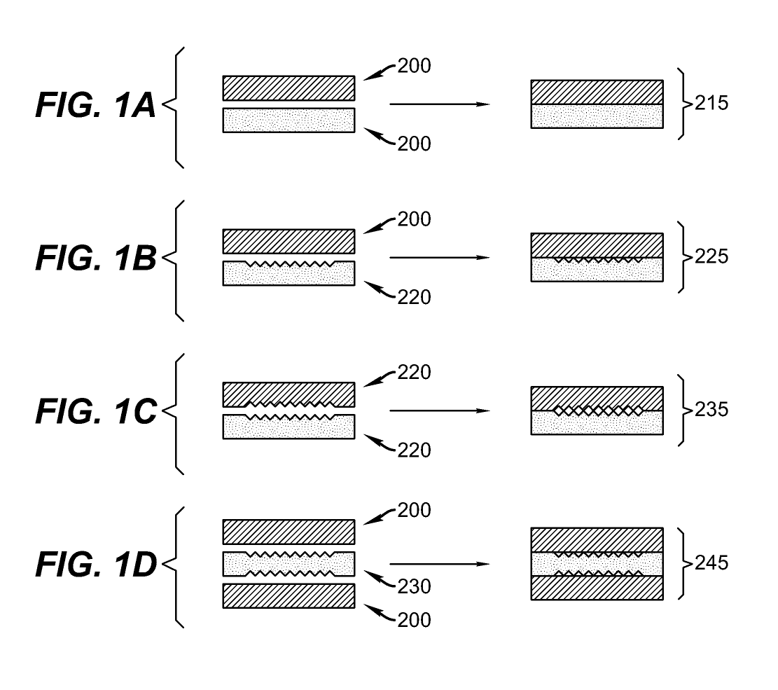

It is desirable to create controlled back pressure in other areas of the delivery head. Referring to FIG. 1A, if two perfectly flat plates 200 are assembled together, these plates will seal against each other to form assembled plate unit 215. If an attempt is made to flow gas in a direction perpendicular to the drawing, the assembled plate unit 215 will not allow the passage of a gas.

Alternatively, one or the both of the plates can have regions with small or microscopic height variations, where the maximum height is level with the main or an original height of the plate. The region of height variations can be referred to as a relief pattern. When plate assemblies are made using plates with a relief pattern, microchannels are formed that results in a flow restriction which helps to create controlled back pressure in other areas of the delivery head.

For example, in FIG. 1B a single flat plate 200 can be mated to a plate 220 containing a relief pattern in a portion of its surface. When these two plates are combined to form assembled plate unit 225, a restrictive opening is formed by contact of the plates. FIGS. 1C and 1D show respectively that two plates containing relief patterns 200 or a plate 230 with relief patterns on both sides and be assembled to produce various diffuser patterns such as assembled plate units 235 and 245.

Broadly described, the relief pattern includes any structure that when assembled provides a desired flow restriction. One example includes simple roughening selected areas of a plate. These can be produced by non-directed roughening methods, such as sanding, sandblasting, or etching processes designed to produce a rough finish.

Alternatively, the area of the micro-channels can be produced by a process producing well-defined or pre-defined features. Such processes include patterning by embossing or stamping. A preferred method of patterning involves photoetching of the part in which a photoresist pattern can be applied and then etching of the metal in the areas where the photoresist is not present. This process can be done several times on a single part in order to provide patterns of different depth as well as to singulate the part from a larger metal sheet.

The parts can also be made by deposition of material onto a substrate. In such a composition, a starting flat substrate plate can be made from any suitable material. A pattern can then be built up on this plate by patterned deposition of materials. The material deposition can be done with optical patterning, such as by applying a uniform coating of an optically sensitive material like a photoresist and then patterning the materials using a light based method with development. The material for relief can also be applied by an additive printed method such as inkjet, gravure, or screen printing.

Direct molding of the parts can also be accomplished. This technique is particularly suitable for polymeric materials, in which a mold of the desired plate can be made and then parts produced using any of the well understood methods for polymer molding.

Typically, the plates are substantially flat structures, varying in thickness from about 0.001 inch to 0.5 inch with relief patterns existing in one or both sides of the plates. When the relief pattern (or patterns) form a channel (or channels), the channel should have an open cross-section available for flow that is very small in order to create a flow restriction that provides a uniform flow backpressure over a linear region so as to suitably diffuse a flow of gas. In order to provide suitable backpressures, the open cross-section for flow typically includes openings that are less than 100,000 μm², preferably less than 10,000 μm².

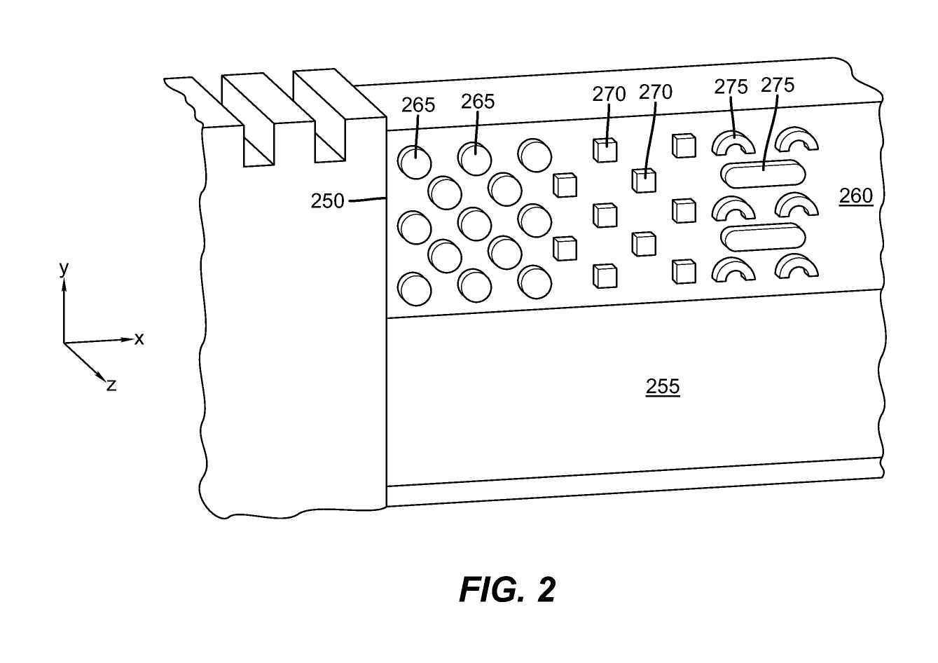

A typical plate structure in a perspective view is shown in FIG. 2, along with axis directions as indicated in the Figure. The surface of the metal plate has a highest area 250 in the z direction. In the case of gas exiting from the diffuser, the gas will arrive in some fashion into a relatively deep recess 255 which allows the gas to flow laterally in the x direction before passing through the diffuser region 260 in the y direction. For purposes of example, several different patterns are shown in the diffuser region 260, including cylindrical posts 265, square posts 270, and arbitrary shapes 275. The height of the features 265, 270, or 275 in the z direction should typically be such that their top surface is at the same as that of a relatively flat area of plate surface 250, such that when a flat plate is superimposed on the plate of FIG. 2 contact is made on the top of the post structures forcing the gas to travel only in the regions left between the post structures. The patterns 265, 270, and 275 are exemplary and any suitable pattern that provides the necessary backpressure can be chosen.

FIG. 2 shows several different diffuser patterns on a single plate structure. It can be desirable to have several different structures on a single diffuser channel to produce specific gas exit patterns. Alternatively, it can be desirable to have only a single pattern if that produces the desired uniform flow. Furthermore, a single pattern can be used in which the size or the density of the features varies depending upon position in the diffuser assembly.

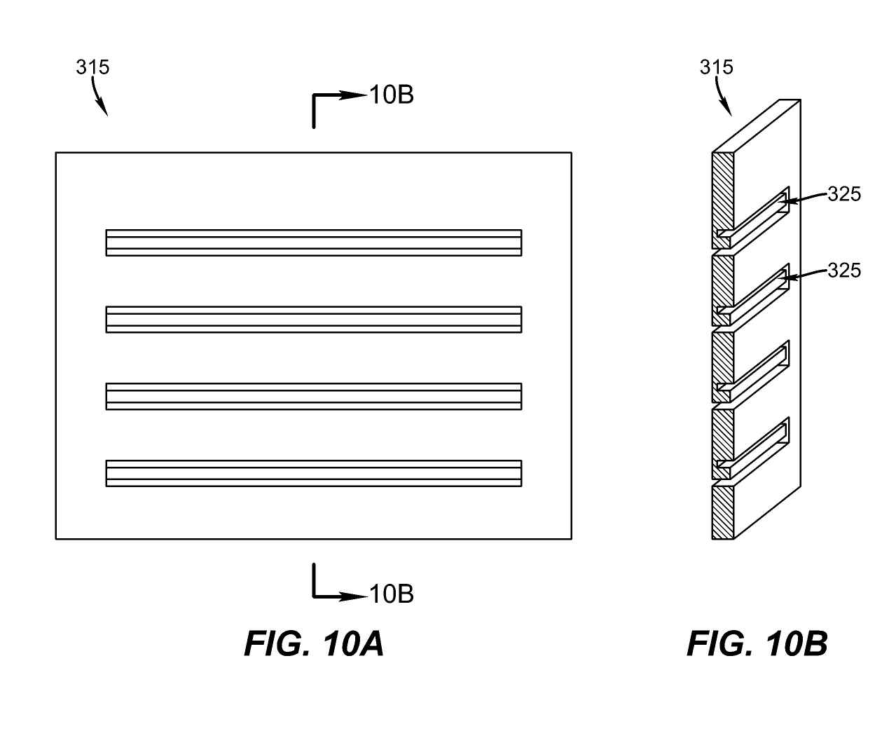

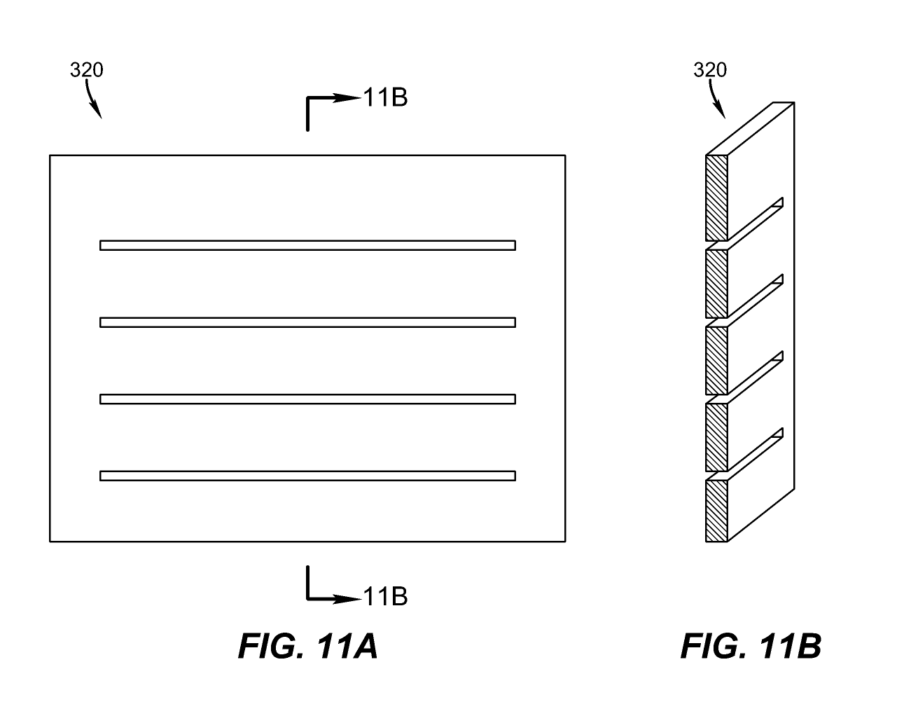

FIGS. 9 through 12B detail the construction of a horizontally disposed gas diffuser plate assembly 140. The diffuser plate assembly 140 is preferably composed of two plates 315 and 320 as shown in perspective exploded view in FIG. 9. The top plate of this assembly 315 is shown in more detail in FIG. 10A (plan view) and 10B (perspective view). The perspective view is taken as a cross-section on the dotted line 10B-10B. The area of the diffuser pattern 325 is shown. The bottom plate of this assembly 320 is shown in more detail in FIG. 11A (plan view) and 11B (perspective view). The perspective view is taken as a cross-section on the dotted line 11B-11B.

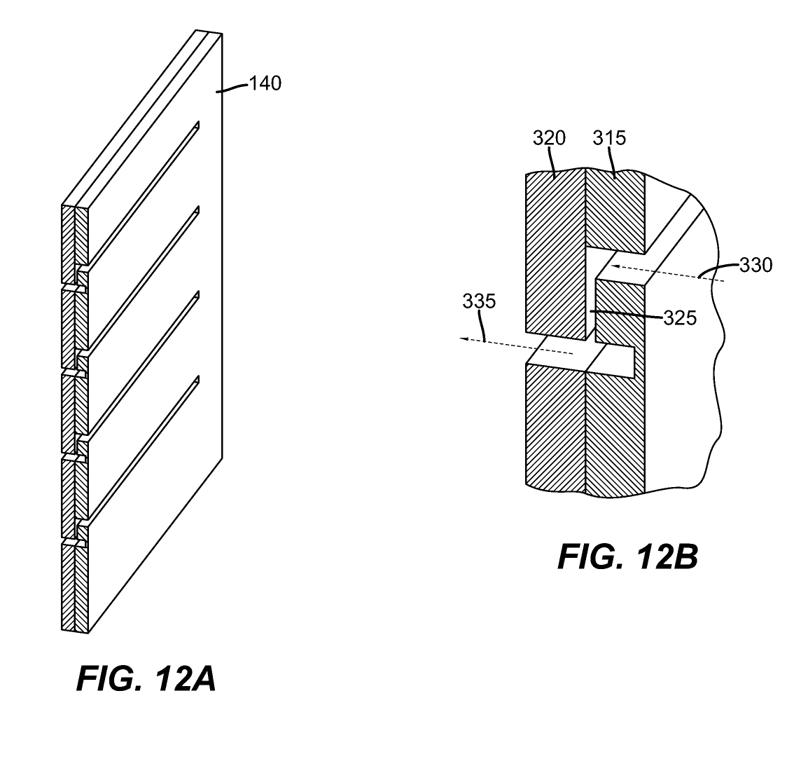

The combined operation of these plates in shown in FIGS. 12A and 12B which show the assembled structure, and a magnification of one of the channels, respectively. In the assembled plate structure, gas supply 330 enters the plate, and is forced to flow through the diffuser region 325 which is now composed of fine channels due to the assembly of plate 315 with plate 320. After passing through the diffuser, diffused gas 335 exits to the output face.

Referring back to FIG. 6, the combination of components shown as connection plate 100, gas chamber plate 110, gas direction plate 120, and base plate 130 can be grouped to provide a delivery assembly 150. Alternate embodiments are possible for delivery assembly 150, including one formed from vertical, rather than horizontal, apertured plates using the coordinate arrangement of FIG. 6.

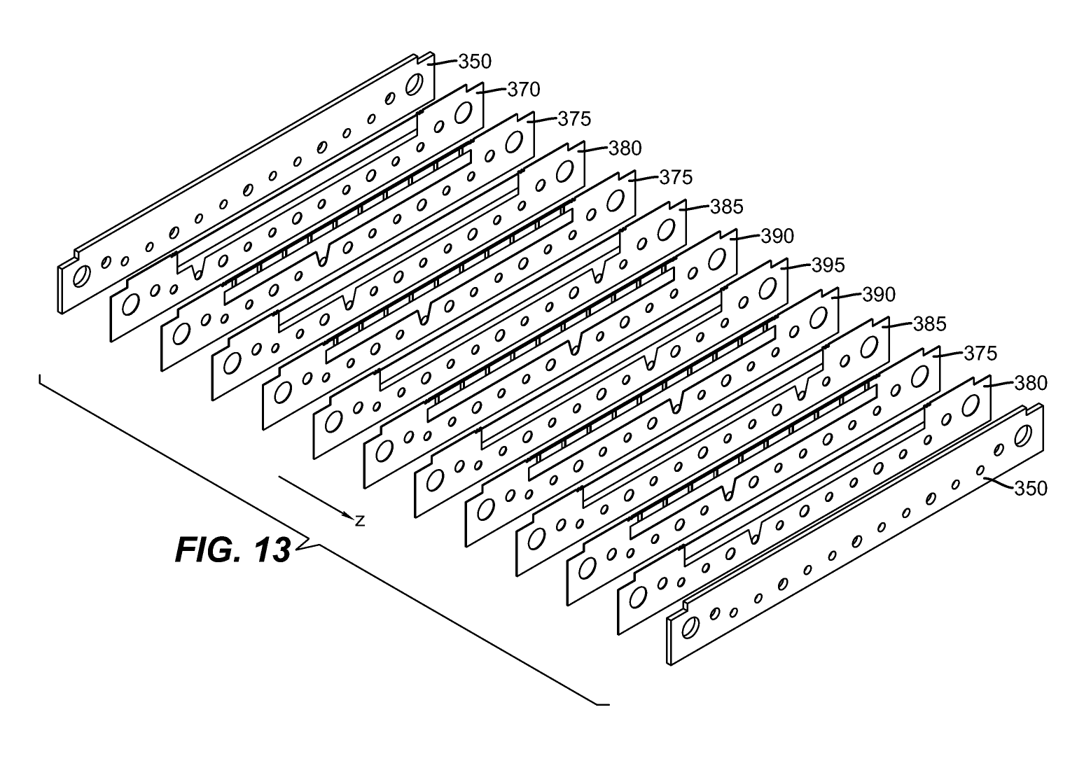

Referring to FIG. 13, there is shown such an alternative embodiment, from a bottom view (that is, viewed from the gas emission side). Such an alternate arrangement can be used for a delivery assembly using a stack of superposed apertured plates that are disposed perpendicularly with respect to the output face of the delivery head.

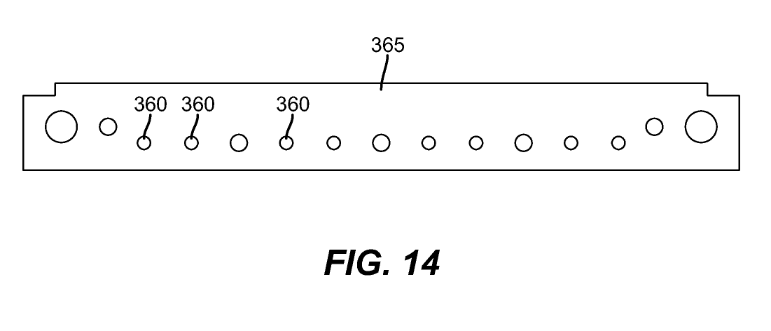

A typical plate outline 365 without a diffuser region is shown in FIG. 14. Supply holes 360 form the supply channels when a series of plates are superposed.

Referring back to FIG. 13, two optional end plates 350 sit at the ends of this structure. The particular elements of this exemplary structure are: Plate 370, connecting supply line #2 to output face via a diffuser; Plate 375, connecting supply line #5 to output face via a diffuser; Plate 380, connecting supply line #4 to output face via a diffuser; Plate 385, connecting supply line #10 to output face via a diffuser; Plate 390, connecting supply line #7 to output face via a diffuser; and Plate 395, connecting supply line #8 to output face via a diffuser. It should be appreciated that by varying the type of plate and its order in the sequence, any combination and order of input channels to output face locations can be achieved.

In the particular embodiment of FIG. 13, the plates have patterns etched only in a single side and the back side (not seen) is smooth except for holes needed for supply lines and assembly or fastening needs (screw holes, alignment holes). Considering any two plates in the sequence, the back of the next plate in the z direction serves as both the flat seal plate against the prior plate and, on its side facing forward in the z direction, as the channels and diffusers for the next elongated opening in the output face.

Alternatively, it is possible to have plates with patterns etched on both sides, and then to use flat spacer plates between them in order to provide the sealing mechanisms

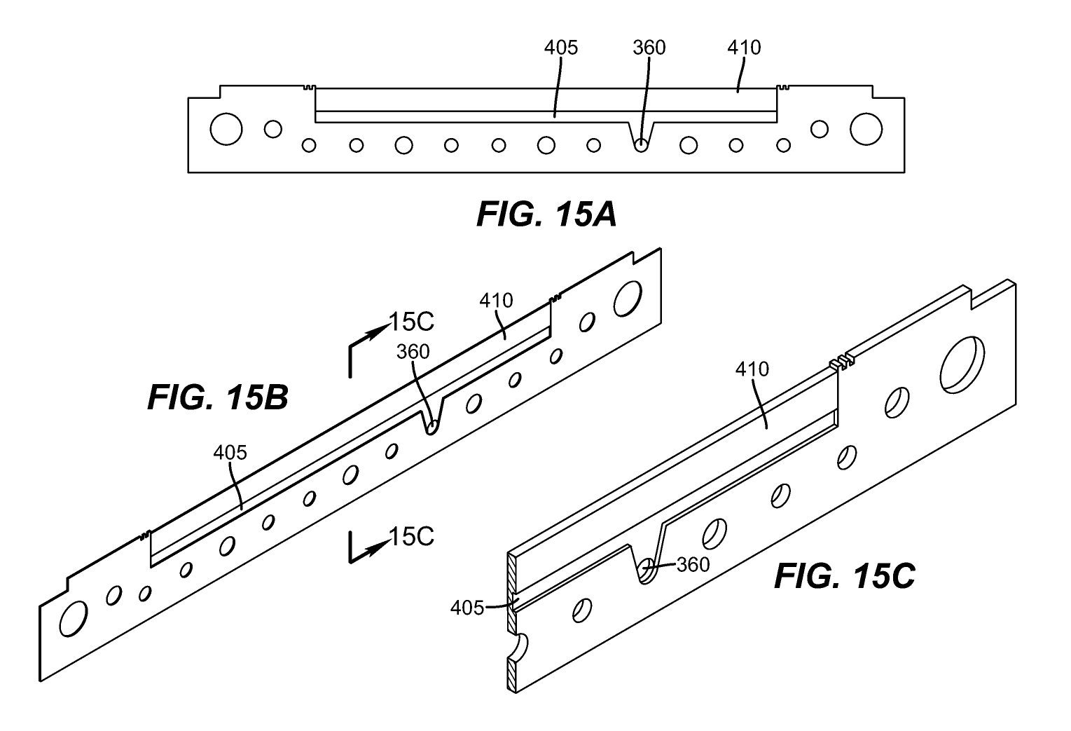

FIGS. 15A-15C show detailed views of a typical plate used in a vertical plate assembly, in this case a plate that connects the 8^{th} supply hole to the output face diffuser area. FIG. 15A shows a plan view, FIG. 15B shows a perspective view, and FIG. 15C shows a perspective section view sectioned at dotted line 15C-15C of FIG. 15B.

In FIG. 15C, a magnification of the plate shows the delivery channel 405 that takes gas from the designated supply line 360 and feeds it to the diffuser area 410 which has a relief pattern (not shown) as described, for example, in earlier FIG. 2.

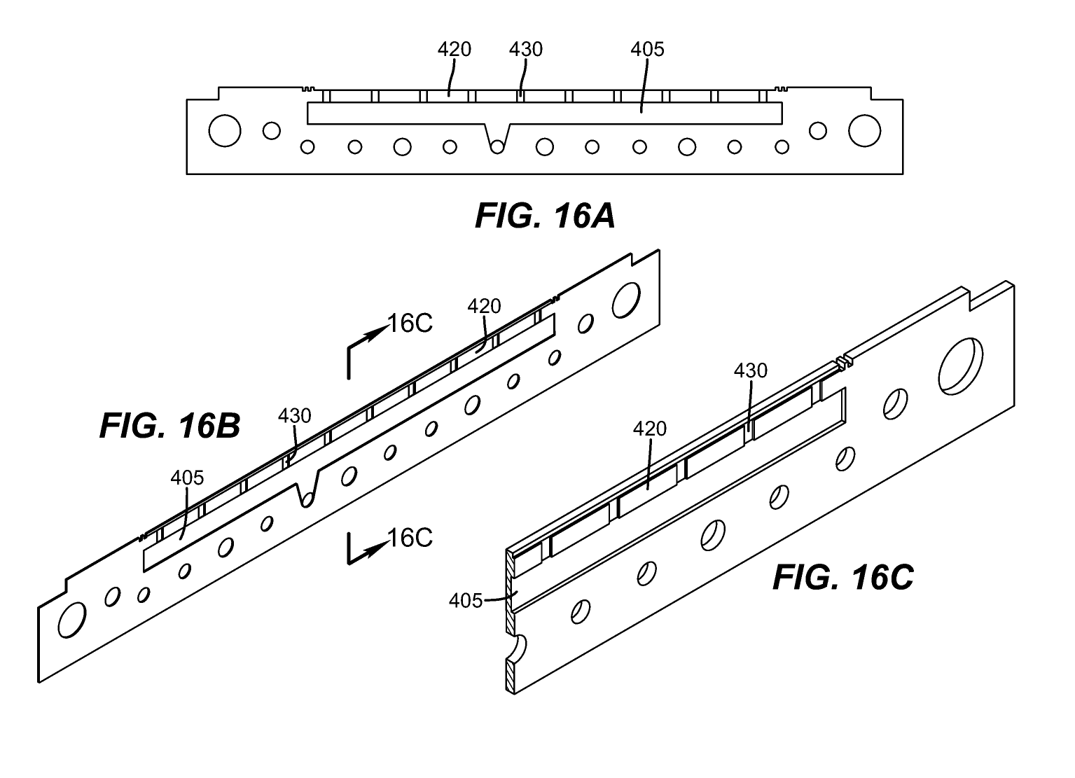

An alternate type of plate with diffuser channel is shown in FIGS. 16A-16C. In this embodiment, the plate connects the 5^{th} supply channel to the output area through a discrete diffuser pattern composed of mainly raised areas 420 with discrete recesses 430, forming a relief pattern, through which gas can pass in an assembled structure. In this case, the raised areas 420 block the flow when the plate is assembled facing another flat plate and the gas should flow in through the discrete recesses, the recesses being patterned in such a way that the individual entrance areas of the diffusing channel do not interconnect. In other embodiments, a substantially continuous network of flow paths are formed in the diffusing channel 260 as shown in FIG. 2, in which posts or other projections or micro-blocking areas separate the microchannels that allow flow of gaseous material.

The ALD deposition apparatus application for this diffuser includes adjacent elongated openings on the output face, some of which supply gas to the output face while others withdraw gas. The diffusers work in both directions, the difference being whether the gas is forced to the output face or pulled from there.

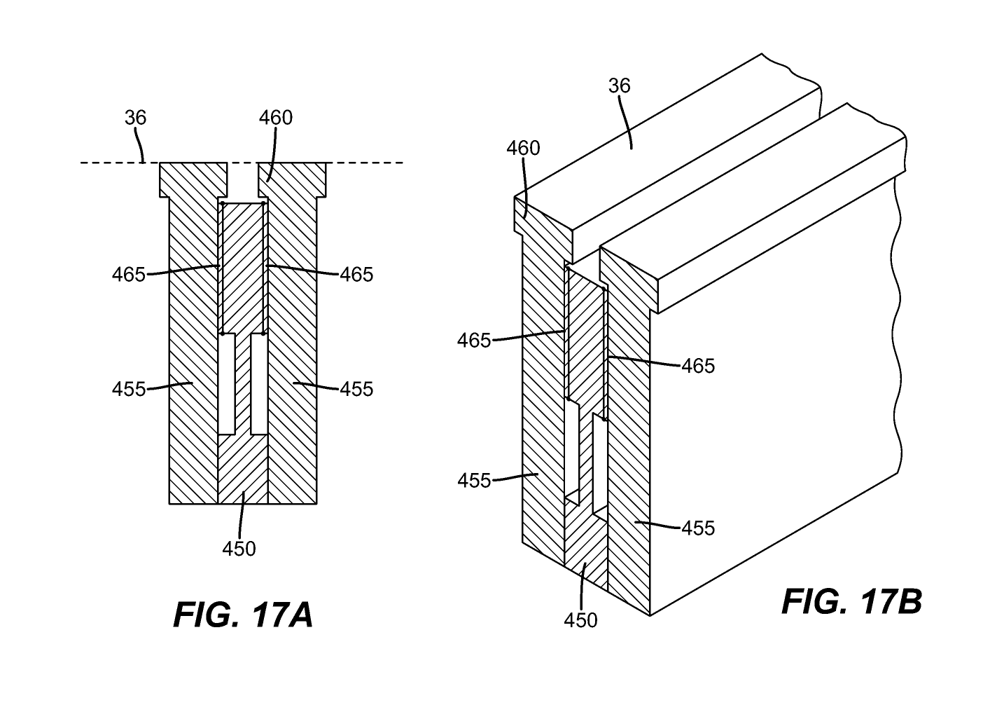

The output of the diffuser channel can be in line of sight contact with the plane of the output face. Alternatively, there may be a need to further diffuse the gas exiting from the diffuser created by the contact of a sealing plate to a plate with a relief pattern. FIGS. 17A and 17B show such a design where a relief-pattern-containing plate 450 is in contact with a sealing plate 455 that has an extra feature 460 that causes gas exiting the diffuser areas 465 to deflect prior to reaching the output face 36.

Returning to FIG. 13, the assembly 350 shows an arbitrary order of plates. For simplicity, letter designations can be given to each type of apertured plate: Purge P, Reactant R, and Exhaust E. A minimal delivery assembly 350 for providing two reactive gases along with the necessary purge gases and exhaust channels for typical ALD deposition can be represented using the full abbreviation sequence: P-E1-R1-E1-P-E2-R2-E2-P-E1-R1-E1-P-E2-R2-E2-P-E1-R1-E1-P, where R1 and R2 represent reactant plates in different orientations, for two different reactant gases used, and E1 and E2 correspondingly represent exhaust plates in different orientations.

Now referring back to FIG. 3, an elongated exhaust channel 154 need not be a vacuum port, in the conventional sense, but can simply be provided to draw off the flow from its corresponding output channel 12, thus facilitating a uniform flow pattern within the channel. A negative draw, just slightly less than the opposite of the gas pressure at neighboring elongated emissive channels, can help to facilitate an orderly flow. The negative draw can, for example, operate with draw pressure at the source (for example, a vacuum pump) of between 0.2 and 1.0 atmosphere, whereas a typical vacuum is, for example, below 0.1 atmosphere.

Use of the flow pattern provided by delivery head 10 provides a number of advantages over conventional approaches, such as those noted earlier in the background section, that pulse gases individually to a deposition chamber. Mobility of the deposition apparatus improves, and the device of the present invention is suited to high-volume deposition applications in which the substrate dimensions exceed the size of the deposition head. Flow dynamics are also improved over earlier approaches.

The flow arrangement used in the present invention allows a very small distance D between delivery head 10 and substrate 20, as was shown in FIG. 3, preferably under 1 mm. Output face 36 can be positioned very closely, to within about 1 mil (approximately 0.025 mm) of the substrate surface. By comparison, earlier approaches such as that described in the U.S. Pat. No. 6,821,563 to Yudovsky, cited earlier, were limited to 0.5 mm or greater distance to the substrate surface, whereas embodiments of the present invention can be practice at less than 0.5 mm, for example, less than 0.450 mm. In fact, positioning the delivery head 10 closer to the substrate surface is preferred in the present invention. In a particularly preferred embodiment, distance D from the surface of the substrate can be 0.20 mm or less, preferably less than 100 μm.

In one embodiment, the delivery head 10 of the present invention can be maintained a suitable separation distance D (FIG. 3) between its output face 36 and the surface of substrate 20, by using a floating system.

The pressure of emitted gas from one or more of output channels 12 generates a force. In order for this force to provide a useful cushioning or “air” bearing (gas fluid bearing) effect for delivery head 10, there should be sufficient landing area, that is, solid surface area along output face 36 that can be brought into close contact with the substrate. The percentage of landing area corresponds to the relative amount of solid area of output face 36 that allows build-up of gas pressure beneath it. In simplest terms, the landing area can be computed as the total area of output face 36 minus the total surface area of output channels 12 and exhaust channels 22. This means that total surface area, excluding the gas flow areas of output channels 12, having a width w1, or of exhaust channels 22, having a width w2, should be maximized as mush as possible. A landing area of 95% is provided in one embodiment. Other embodiments can use smaller landing area values, such as 85% or 75%, for example. Adjustment of gas flow rate can also be used in order to alter the separation or cushioning force and thus change distance D accordingly.

It should be appreciated that there are advantages to providing a gas fluid bearing, so that delivery head 10 is substantially maintained at a distance D above substrate 20. This allows essentially frictionless motion of delivery head 10 using any suitable type of transport mechanism. Delivery head 10 can then be caused to “hover” above the surface of substrate 20 as it is channeled back and forth, sweeping across the surface of substrate 20 during materials deposition.

The deposition heads include a series of plates assembled in a process. The plates can be horizontally disposed, vertically disposed, or include a combination thereof.

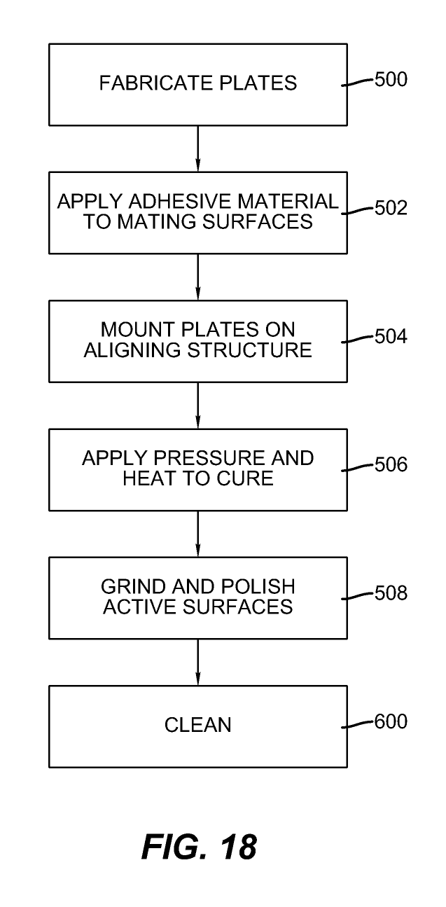

One example of a process of assembly is shown in FIG. 18. Basically, the process of assembling a delivery head for thin-film material deposition onto a substrate includes fabricating a series of plates (step 500 of FIG. 18), at least a portion thereof containing relief patterns for forming a diffuser element, and attaching the plates to each other in sequence so as to form a network of supply lines connected to one or more diffuser elements. Such a process optionally involves placing a spacer plate containing no relief pattern which is placed between at least one pair of plates each containing a relief pattern.

In one embodiment, the order of assembly produces a plurality of flow paths in which each of the plurality of elongated output openings of the first gaseous material in the output face is separated from at least one of the plurality of elongated output openings of the second gaseous material in the output face by at least one of the plurality of elongated output openings of the third gaseous material in the output face. In another embodiment, the order of assembly produces a plurality of flow paths in which each of the plurality of elongated output openings of the first gaseous material in the output face is separated from at least one of the plurality of elongated output openings of the second gaseous material in the output face by at least one elongated exhaust opening in the output face which elongated exhaust opening is connected to an exhaust port in order to pull gaseous material from the region of the output face during deposition.

The plates can first be fabricated by a suitable means involving but not limited to the processes of stamping, embossing, molding, etching, photoetching, or abrasion.

A sealant or adhesive material can be applied to the surfaces of the plates in order to attach them together (step 502 of FIG. 18). Since these plates can contain fine patterning areas, it is critical that an adhesive application not apply an excess of adhesive that might block critical areas of the head during assembly. Alternatively, the adhesive can be applied in a patterned form so as not to interfere with critical areas of the internal structure, while still providing sufficient adhesion to allow mechanical stability. The adhesive can also be a byproduct of one of the process steps, such as residual photoresist on the plate surface after an etching process.

The adhesive or sealant can be selected from many known materials of that class such as epoxy based adhesives, silicone based adhesives, acrylate based adhesives, or greases.

The patterned plates can be arranged into the proper sequence to result in the desired association of inlet to output face elongated openings. The plates are typically assembled on some sort of aligning structure (step 504). This aligning structure can be any controlled surface or set of surfaces against which rest some surface of the plates, such that the plates as assembled will already be in a state of excellent alignment. A preferred aligning structure is to have a base portion with alignment pins, which pins are meant to interface with holes that exist in special locations on all of the plates. Preferably there are two alignment pins. Preferably one of these alignment holes is circular while the other is a slot to not over-constrain the parts during assembly.

Once all of the parts and their adhesive are assembled on the alignment structure, a pressure plate is applied to the structure and pressure and or heat are applied to cure the structure (step 506).

Although the alignment from the above mentioned pins already provides an excellent alignment of the structure, variations in the manufacturing process of the plates may result in the output face surface not being sufficiently flat for proper application. In such case, it can be useful to grind and polish the output face as a complete unit or order to obtain the desired surface finish (step 508). Finally, a cleaning step may be desired in order to permit operation of the deposition head without leading to contamination (step 600).

As will be understood by the skilled artisan, a flow diffuser such as the one(s) described herein can be useful in a variety of devices used to distribute gaseous fluids onto a substrate. Typically, the flow diffuser includes a first plate and a second plate, at least one of the first plate and the second plate including a relief pattern portion. The first plate and the second plate are assembled to form an elongated output opening with a flow diffusing portion defined by the relief pattern portion, wherein flow diffusing portion is capable of diffusing the flow of a gaseous (or liquid) material. Diffusing of the flow of a gaseous (or liquid) material is accomplished by passing the gaseous (or liquid) material through a flow diffusing portion defined by the relief pattern portion formed by assembling the first plate and the second plate. The relief pattern portion is typically located between facing plates and connects an elongated inlet and an elongated outlet or output opening for the flow of the gaseous (or liquid) material.

Although the method using stacked apertured plates is a particularly useful way of constructing the delivery head, there are a number of other methods for building such structures that can be useful in alternate embodiments. For example, the apparatus can be constructed by direct machining of a metal block, or of several metal blocks adhered together. Furthermore, molding techniques involving internal mold features can be employed, as will be understood by the skilled artisan. The apparatus can also be constructed using any of a number of stereolithography techniques.

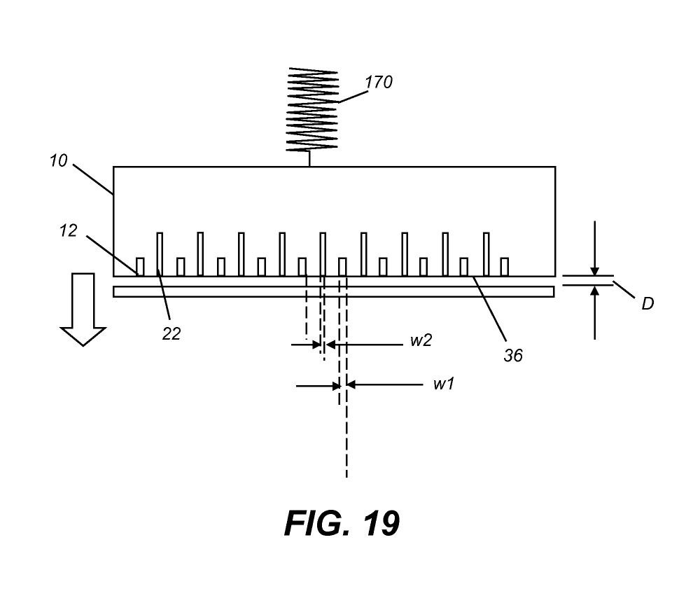

One advantage offered by delivery head 10 of the present invention relates to maintaining a suitable separation distance D (shown in FIG. 3) between its output face 36 and the surface of substrate 20. FIG. 19 shows some key considerations for maintaining distance D using the pressure of gas flows emitted from delivery head 10.

In FIG. 19, a representative number of output channels 12 and exhaust channels 22 are shown. The pressure of emitted gas from one or more of output channels 12 generates a force, as indicated by the downward arrow in this figure. In order for this force to provide a useful cushioning or “air” bearing (gas fluid bearing) effect for delivery head 10, there should be sufficient landing area, that is, solid surface area along output face 36 that can be brought into close contact with the substrate. The percentage of landing area corresponds to the relative amount of solid area of output face 36 that allows build-up of gas pressure beneath it. In simplest terms, the landing area can be computed as the total area of output face 36 minus the total surface area of output channels 12 and exhaust channels 22. This means that total surface area, excluding the gas flow areas of output channels 12, having a width w1, or of exhaust channels 22, having a width w2, should be maximized as much as possible. A landing area of 95% is provided in one embodiment. Other embodiments can use smaller landing area values, such as 85% or 75%, for example. Adjustment of gas flow rate can also be used in order to alter the separation or cushioning force and thus change distance D accordingly.

It should be appreciated that there are advantages to providing a gas fluid bearing, so that delivery head 10 is substantially maintained at a distance D above substrate 20. This allows essentially frictionless motion of delivery head 10 using any suitable type of transport mechanism. Delivery head 10 can then be caused to “hover” above the surface of substrate 20 as it is channeled back and forth, sweeping across the surface of substrate 20 during materials deposition.

As shown in FIG. 19, delivery head 10 may be too heavy, so that the downward gas force is not sufficient for maintaining the needed separation. In such a case, auxiliary lifting components, such as a spring 170, magnet, or other device, can be used to supplement the lifting force. In other cases, gas flow can be high enough to cause the opposite problem, so that delivery head 10 may be forced apart from the surface of substrate 20 by too great a distance, unless additional force is exerted. In such a case, spring 170 can be a compression spring, to provide the additional needed force to maintain distance D (downward with respect to the arrangement of FIG. 19). Alternately, spring 170 can be a magnet, elastomeric spring, or some other device that supplements the downward force.

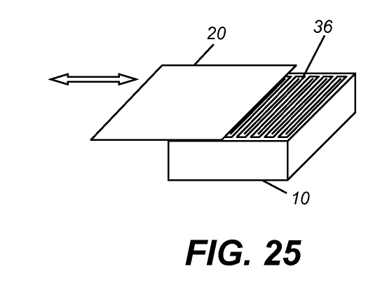

Alternately, delivery head 10 can be positioned in some other orientation with respect to substrate 20. For example, substrate 20 can be supported by the air bearing effect, opposing gravity, so that substrate 20 can be moved along delivery head 10 during deposition. One embodiment using the air bearing effect for deposition onto substrate 20, with substrate 20 cushioned above delivery head 10 is shown in FIG. 25. Movement of substrate 20 across output face 36 of delivery head 10 is in a direction along the double arrow as shown.

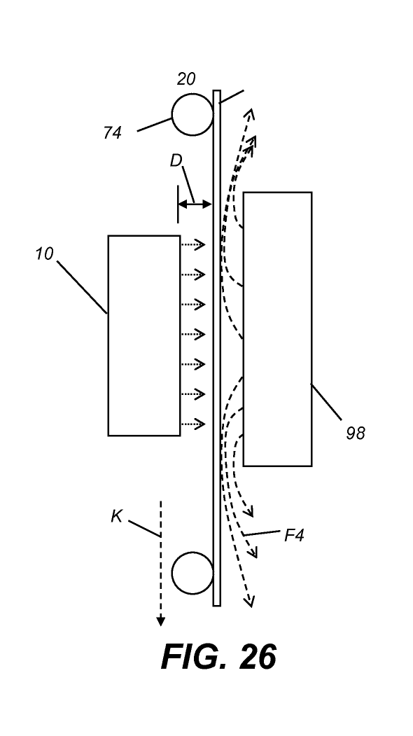

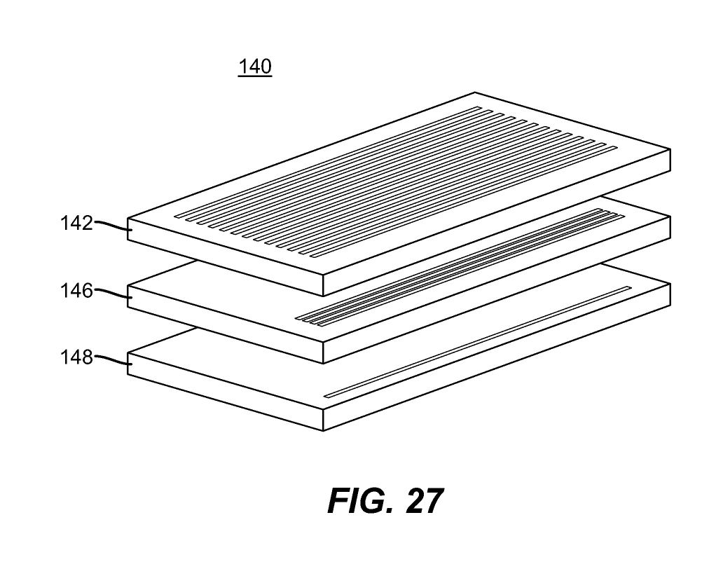

The alternate embodiment of FIG. 26 shows substrate 20 on a substrate support 74, such as a web support or rollers, moving in direction K between delivery head 10 and a gas fluid bearing 98. In this embodiment, delivery head 10 has an air-bearing or, more appropriately, a gas fluid-bearing effect and cooperates with gas fluid bearing 98 in order to maintain the desired distance D between output face 36 and substrate 20. Gas fluid bearing 98 can direct pressure using a flow F4 of inert gas, or air, or some other gaseous material. It is noted that, in the present deposition system, a substrate support or holder can be in contact with the substrate during deposition, which substrate support can be a means for conveying the substrate, for example a roller. Thus, thermal isolation of the substrate as it is being treated is not a requirement of the present system.

As was particularly described with reference to FIGS. 5A and 5B, delivery head 10 incorporates movement relative to the surface of substrate 20 in order to perform its deposition function. This relative movement can be obtained in a number of ways, including movement of either or both delivery head 10 and substrate 20, such as by movement of an apparatus that provides a substrate support. Movement can be oscillating or reciprocating or can be continuous movement, depending on how many deposition cycles are needed. Rotation of a substrate can also be used, particularly in a batch process, although continuous processes are preferred. An actuator can be coupled to the body of the delivery head, such as mechanically connected. An alternating force, such as a changing magnetic force field, can alternately be used.

Typically, ALD involves multiple deposition cycles, building up a controlled film depth with each cycle. Using the nomenclature for types of gaseous materials given earlier, a single cycle can, for example in a simple design, provide one application of first reactant gaseous material O and one application of second reactant gaseous material M.

The distance between output channels for O and M reactant gaseous materials determines the needed distance for reciprocating movement to complete each cycle. For the example delivery head 10 of FIG. 6 can have a nominal channel width of 0.1 inches (2.54 mm) in width between a reactant gas channel outlet and the adjacent purge channel outlet. Therefore, for the reciprocating motion (along the y axis as used herein) to allow all areas of the same surface to see a full ALD cycle, a stroke of at least 0.4 inches (10.2 mm) can be necessary. For this example, an area of substrate 20 can be exposed to both first reactant gaseous material O and second reactant gaseous material M with movement over this distance. Alternatively, a delivery head can move much larger distances for its stroke, even moving from one end of a substrate to another. In this case, the growing film can be exposed to ambient conditions during periods of its growth, causing no ill effects in many circumstances of use. In some cases, consideration for uniformity can necessitate a measure of randomness to the amount of reciprocating motion in each cycle, such as to reduce edge effects or build-up along the extremes of reciprocation travel.

A delivery head 10 can have only enough output channels 12 to provide a single cycle. Alternately, delivery head 10 can have an arrangement of multiple cycles, enabling it to cover a larger deposition area or enabling its reciprocating motion over a distance that allows two or more deposition cycles in one traversal of the reciprocating motion distance.

For example, in one particular application, it was found that each O-M cycle formed a layer of one atomic diameter over about ¼ of the treated surface. Thus, four cycles, in this case, are needed to form a uniform layer of 1 atomic diameter over the treated surface. Similarly, to form a uniform layer of 10 atomic diameters in this case, then, 40 cycles can be needed.

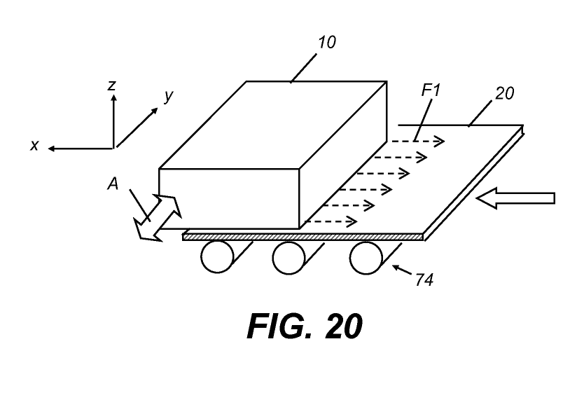

An advantage of the reciprocating motion used for a delivery head 10 of the present invention is that it allows deposition onto a substrate 20 whose area exceeds the area of output face 36. FIG. 20 shows schematically how this broader area coverage can be effected, using reciprocating motion along the y axis as shown by arrow A and also movement orthogonal or transverse to the reciprocating motion, relative to the x axis. Again, it should be emphasized that motion in either the x or y direction, as shown in FIG. 20, can be effected either by movement of delivery head 10, or by movement of substrate 20 provided with a substrate support 74 that provides movement, or by movement of both delivery head 10 and substrate 20.

In FIG. 20 the relative motion directions of the delivery head and the substrate are perpendicular to each other. It is also possible to have this relative motion in parallel. In this case, the relative motion needs to have a nonzero frequency component that represents the oscillation and a zero frequency component that represents the displacement of the substrate. This combination can be achieved by an oscillation combined with displacement of the delivery head over a fixed substrate; an oscillation combined with displacement of the substrate relative to a fixed substrate delivery head; or any combinations wherein the oscillation and fixed motion are provided by movements of both the delivery head and the substrate.

Advantageously, delivery head 10 can be fabricated at a smaller size than is possible for many types of deposition heads. For example, in one embodiment, output channel 12 has width w1 of about 0.005 inches (0.127 mm) and is extended in length to about 3 inches (75 mm).

In a preferred embodiment, ALD can be performed at or near atmospheric pressure and over a broad range of ambient and substrate temperatures, preferably at a temperature of under 300° C. Preferably, a relatively clean environment is needed to minimize the likelihood of contamination; however, full “clean room” conditions or an inert gas-filled enclosure are not necessary in order to obtain acceptable performance when using preferred embodiments of the apparatus of the present invention.

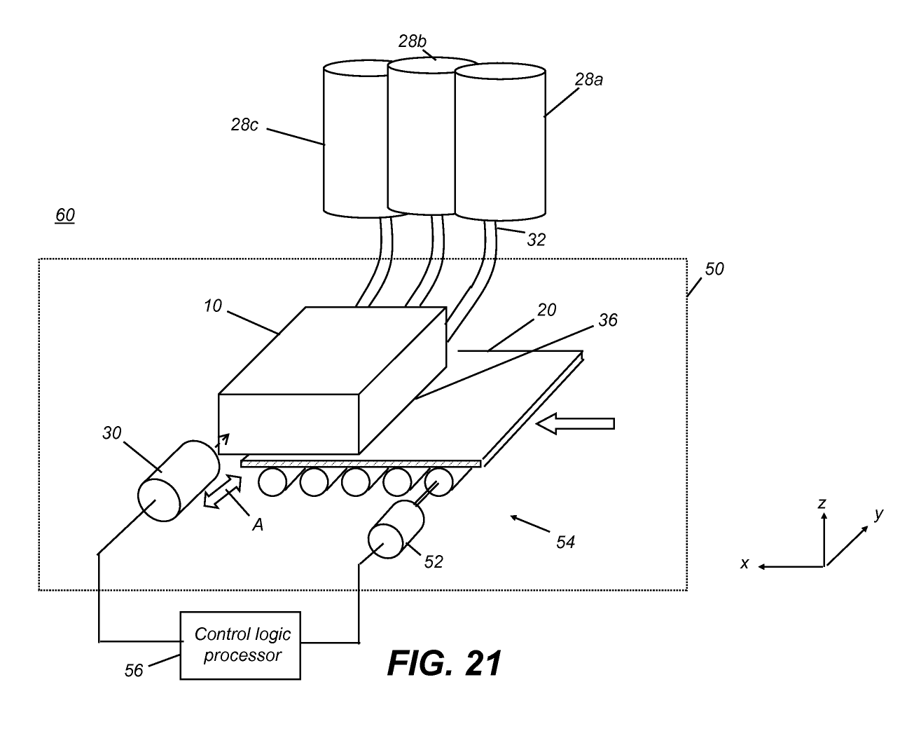

FIG. 21 shows an Atomic Layer Deposition (ALD) system 60 having a chamber 50 for providing a relatively well-controlled and contaminant-free environment. Gas supplies 28a, 28b, and 28c provide the first, second, and third gaseous materials to delivery head 10 through supply lines 32. The optional use of flexible supply lines 32 facilitates ease of movement of delivery head 10. For simplicity, optional vacuum vapor recovery apparatus and other support components are not shown in FIG. 21, but can also be used. A transport subsystem 54 provides a substrate support that conveys substrate 20 along output face 36 of delivery head 10, providing movement in the x direction, using the coordinate axis system employed in the present disclosure. Motion control, as well as overall control of valves and other supporting components, can be provided by a control logic processor 56, such as a computer or dedicated microprocessor assembly, for example. In the arrangement of FIG. 21, control logic processor 56 controls an actuator 30 for providing reciprocating motion to delivery head 10 and also controls a transport motor 52 of transport subsystem 54. Actuator 30 can be any of a number of devices suitable for causing back-and-forth motion of delivery head 10 along a moving substrate 20 (or, alternately, along a stationary substrate 20).

FIG. 21 shows an alternate embodiment of an Atomic Layer Deposition (ALD) system 70 for thin film deposition onto a web substrate 66 that is conveyed past delivery head 10 along a web conveyor 62 that acts as a substrate support. The web itself can be the substrate or can provide support for an additional substrate. A delivery head transport 64 conveys delivery head 10 across the surface of web substrate 66 in a direction transverse to the web travel direction. In one embodiment, delivery head 10 is impelled back and forth across the surface of web substrate 66, with the full separation force provided by gas pressure. In another embodiment, delivery head transport 64 uses a lead screw or similar mechanism that traverses the width of web substrate 66. In another embodiment, multiple delivery heads 10 are used, at suitable positions along web 62.

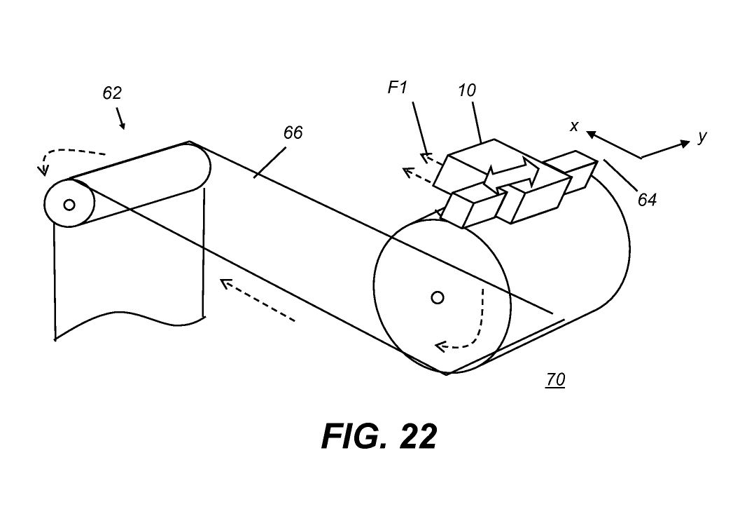

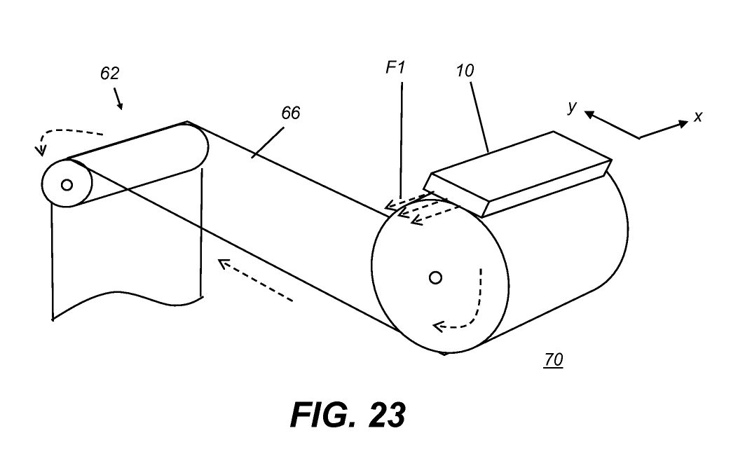

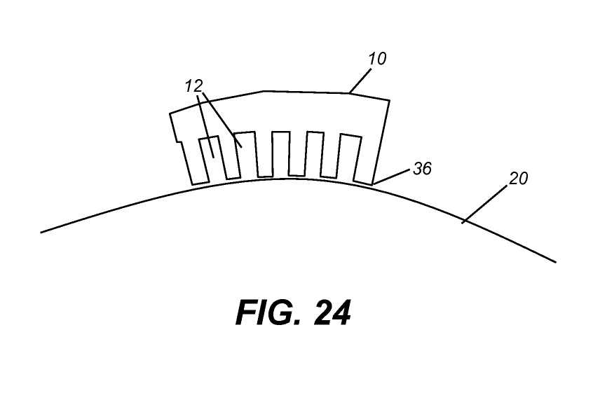

FIG. 23 shows another Atomic Layer Deposition (ALD) system 70 in a web arrangement, using a stationary delivery head 10 in which the flow patterns are oriented orthogonally to the configuration of FIG. 22. In this arrangement, motion of web conveyor 62 itself provides the movement needed for ALD deposition. Reciprocating motion can also be used in this environment. Referring to FIG. 24, an embodiment of a portion of delivery head 10 is shown in which output face 36 has an amount of curvature, which might be advantageous for some web coating applications. Convex or concave curvature can be provided.

In another embodiment that can be particularly useful for web fabrication, ALD system 70 can have multiple delivery heads 10, or dual delivery heads 10, with one disposed on each side of substrate 66. A flexible delivery head 10 can alternately be provided. This provides a deposition apparatus that exhibits at least some conformance to the deposition surface.

In another embodiment, one or more output channels 12 of delivery head 10 can use the transverse gas flow arrangement that is disclosed in US Patent Application Publication No. US 2007/0228470. In such an embodiment, gas pressure that supports separation between delivery head 10 and substrate 20 can be maintained by some number of output channels 12, such as by those channels that emit purge gas (channels labeled I in FIGS. 4-5B), for example. Transverse flow can then be used for one or more output channels 12 that emit the reactant gases (channels labeled O or M in FIGS. 4-5B).

The present invention is advantaged in its capability to perform deposition onto a variety of different types of substrates over a broad range of temperatures, including room or near-room temperature in some embodiments, and deposition environments. The present invention can operate in a vacuum environment, but is particularly well suited for operation at or near atmospheric pressure. The present invention can be employed in low temperature processes at atmospheric pressure conditions, which process can be practiced in an unsealed environment, open to ambient atmosphere. The present invention is also adaptable for deposition on a web or other moving substrate, including deposition onto a large area substrate.

Thin film transistors, for example, having a semiconductor film made according to the present method can exhibit a field effect electron mobility that is greater than 0.01 cm²/Vs, preferably at least 0.1 cm²/Vs, more preferably greater than 0.2 cm²/Vs. In addition, n-channel thin film transistors having semiconductor films made according to the present invention are capable of providing on/off ratios of at least 10⁴, advantageously at least 10⁵. The on/off ratio is measured as the maximum/minimum of the drain current as the gate voltage is swept from one value to another that are representative of relevant voltages which might be used on the gate line of a display. A typical set of values would be −10V to 40V with the drain voltage maintained at 30V.

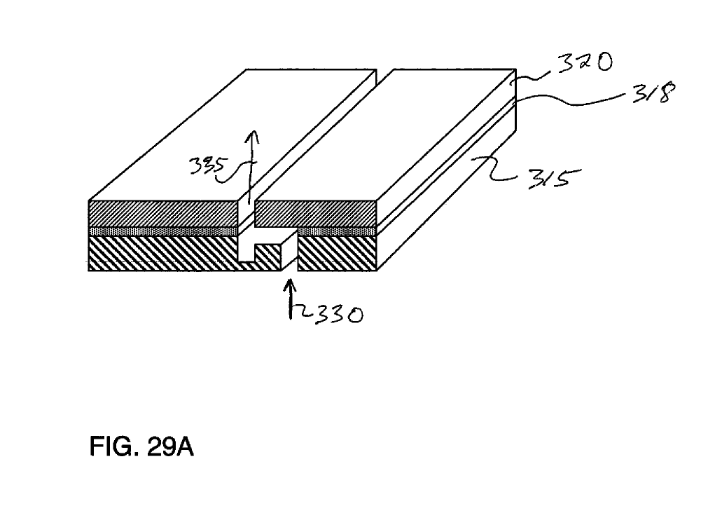

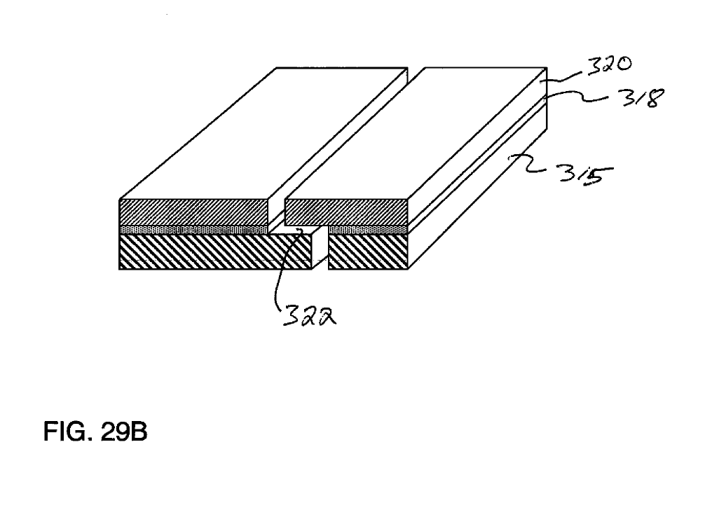

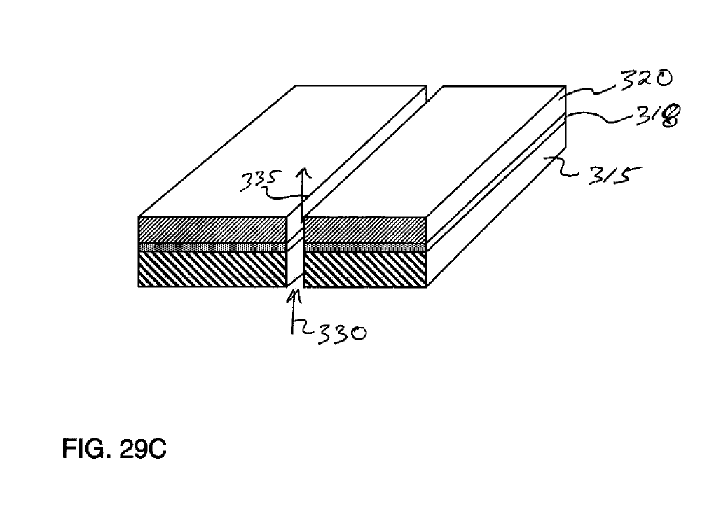

Referring to FIGS. 29A and 29B, and back to FIGS. 6 through 18, perspective cross-sectional views of an assembled two plate diffuser assembly are shown. FIG. 29C shows a perspective cross-sectional view of an assembled two plate gaseous fluid flow channel fabricated in the same manner as the two plate diffuser assembly shown in FIGS. 29A and 29B.

The delivery head 10, also referred to as a fluid distribution manifold, includes a first plate 315 and a second plate 320. At least a portion of at least the first plate 315 and the second plate 320 define a relief pattern, described above with reference to at least FIGS. 1A-2. A metal bonding agent 318 is disposed between the first plate 315 and the second plate 320 such that the first plate 315 and the second plate 320 form a fluid flow directing pattern defined by the relief pattern after the first plate 315 and the second plate 320 are bonded together.

The metal bonding agent 318 can be any material composed predominantly of a metal, which under conditions of heating or pressure acts as a bonding agent between the first plate and the second plate (typically, two metal substrates). Typical processes involving metal bonding are soldering and brazing. In both processes, two metals are joined by melting or providing a melted filler metal between metal parts to be joined. Soldering is arbitrarily distinguished from brazing in that soldering filler metals melt at lower temperatures, often below 400° F., while brazing metals melt at higher temperatures, often above 400° F.

Common low temperature or soldering bonding metals are pure materials or alloys containing lead, tin, copper, zinc, silver, indium, or antimony. Common higher temperature or brazing bonding metals are pure materials or alloys containing aluminum, silicon, copper, phosphorous, zinc, gold, silver, or nickel. In general, any pure metal or combination of metals capable of melting at an acceptable temperature and capable of wetting the surfaces of the parts to be joined is acceptable.

Often additional components can be provided with the metal bonding agent 318 in order to ensure that the bonding metal adheres well to the surface being bonded. One such component is flux, which is any material applied in conjunction with the metal bonding agent serving the purpose of cleaning and preparing the surfaces to be bonded. It is also possible that thin layers of various alternate metals need to be applied to the surface of the metal parts to promote adhesion of the filler metal. One example would be to apply a thin layer of nickel on stainless steel to promote adhesion of silver.

Bonding metals can be applied in any fashion resulting in the desired quantity of bonding metal during the bonding process. The bonding metal can be applied as a separate sheet of thin metal that is placed between the parts. The bonding metal can be provided in the form of a solution or paste that is applied to the parts to be bonded. This solution or paste often contains a binder, a solvent, or a combination of a binder and a solvent vehicle which can be removed before or during the metal bonding process.

Alternatively, the metal bonding agent 318 can be supplied by a formal deposition method onto the parts. Examples of such deposition methods are sputtering, evaporation, and electroplating. The deposition methods can apply pure metals, metal alloys, or layered structures including various metals.

The bonding process involves assembling the parts to be bonded followed by application of at least heat, or pressure, or a combination of heat and pressure. The heat can be applied by resistive, inductive, convective, radiative, or flame heating. It is often desirable to control the atmosphere of the bonding process to reduce oxidation of the metal components. Processes can occur at any pressure ranging from greater than atmospheric pressure to high vacuum processes. The composition of the gases in contact with the materials to be bonded should be largely devoid of oxygen, and may advantageously contain nitrogen, hydrogen, argon or other inert gases or reducing gases.

The flow directing pattern can be defined by a relief pattern that remains free of the metal bonding agent. While the metal bonding agent 318 can be applied uniformly to the metal plates to be joined, that results in bonding agent present on all internal surface of the assembled distribution manifold which may lead to problems of chemical compatibility. Furthermore, the presence of excess bonding metal during the assembly operation may lead to plugging of internal passages in the distribution manifold as the bonding agent flows during the high temperature assembly process.

Prior to assembly, the metal bonding agent 318 can exist preferentially only on surfaces that will be bonded, and not in the relief patterns. This can be accomplished by using a separate sheet of bonding metal that has been patterned to reflect the bonding surface of the plates. Alternatively, if the metal bonding is applied as a liquid precursor, the application can employ a technique such as roller printing where either or both of the pattern of the printing roller or the relief of the plates allow bonding agent to be applied only where desired.

When the relief pattern is formed by an etching process, a particularly preferred method is to apply a bonding agent 318 as a film on the metal plates prior to the etching process. After the bonding agent is applied to the plate 315 or 320, a suitable mask is provided over the metal bonding agent. A suitable etchant then etches both the metal plate and superimposed bonding materials, for example, in a single etching process. As a result, a very precise pattern of bonding material can be obtained in the same process step as the metal plate relief pattern is etched. Alternatively, the metal bonding agent 318 and the plate to which the metal bonding agent has been applied, can be etched in separate process steps using the same mask. This also yields a very precise pattern of bonding material.

The relative position and shape of the first plate 315 and the second plate 320 can vary depending on the specific application contemplated. For example, the second plate can include a relief portion that is disposed opposite the relief portion of the first plate, shown in FIGS. 29A and 29C. In this case, a fluid flow directing pattern is formed by a combination of the relief patterns in each of the plates 315, 320 and the effect of sealing the relief pattern at its edges using the bonding metal 318.

Alternatively, the second plate can include a relief portion disposed offset from the relief portion of the first plate, shown in FIG. 29B. As shown in FIG. 29B, some of the relief patterns in the first plate 315 are opposite a non relieved section in the second plate 320. Even though there is no relief pattern in the second plate 320, areas of either of both of first plate 315 and second plate 320 that are without bonding agent do not form a complete seal and can provide a sometimes desirable very high resistance to flow. Thus, a fluid flow directing pattern 322 can be formed by the plate or plates without a relief pattern but having a pattern of bonding metal. In this case, the bonding metal can be patterned by any of the above methods. In addition, the bonding metal can be patterned by an etching process with an etchant that attacks the bonding metal but not the underlying plate material.

During the assembly of the delivery head 10, also referred to as a fluid distribution manifold, a bonding metal situated between the relief containing plates should seal the areas in between relief features. Sufficient bonding metal should be applied to seal the features, while an excess of bonding metal may flow undesirably to other parts of the manifold causing plugging or lack of surface reactivity. Furthermore, the output face of the fluid distribution manifold should be sufficiently flat, preferably with little or no grinding after construction of the fluid distribution manifold.

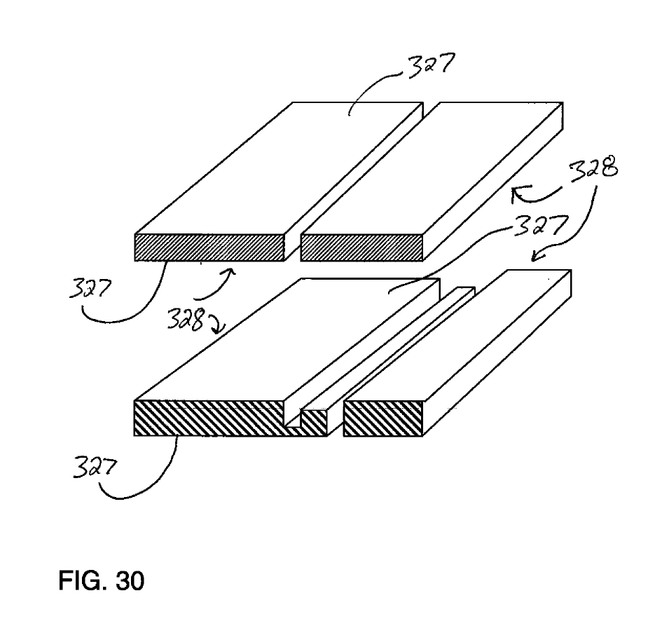

Referring to FIG. 30, to facilitate sufficient sealing and output face flatness, the fluid distribution manifold includes a first plate 315 and a second plate 320 with at least a portion of at least the first plate 315 and the second plate 320 defining a relief pattern. At least one of the first plate 315 and the second plate 320 includes a mirrored surface finish (designated using reference number 327). A bonding agent is disposed between the first plate and the second plate such that the first plate and the second plate forms a fluid flow directing pattern defined by the relief pattern.

As used herein, the term mirrored surface finish is a surface including a surface finish that requires minimal polishing before or after device assembly. Surface finish can be described by the Ra, defined in ASME B46.1-2002 as the “Arithmetic Average Deviation of the Assessed Profile”, and defined in ISO 4287-1997. The Ra of a surface is obtained by measuring the microscopic profile of a surface. From the profile, and average surface height is determined. The Ra is the average absolute deviation from that average surface height.

The fluid distribution manifold contains internal or external mirrored surface finishes including a surface finish of preferably less than 16 micro-inches Ra, more preferably less than or equal to 8 micro-inches Ra, and most preferably less than or equal to 4 micro-inches Ra. Although a surface finish of 4 micro-inches is most preferred, depending on the specific application contemplated, a surface finish of 8 micro-inches or 16 micro-inches is often used because they can provide adequate performance at a reasonable cost.

The fluid distribution manifold can have a plate 315 or 320 including an output face, with the output face including the mirrored surface finish. Flatness of the output face is important because floating height of a substrate is reduced with reduced flatness, and undesired gas mixing can increase if there is roughness or scratches that either retain chemicals used in the deposition process, or create passageways for gas mixing. Flatness can conventionally be achieved by grinding the output face after assembly. Unfortunately this leads to increased cost, and is difficult with large manifolds that have thin top plates because the grinding process may thin these plates to a point where they fail structurally. If the fluid distribution manifold is assembled with a plate 315 or 320 already containing a surface representing the output face that has a mirror finish, most of all of the post assembly grinding can be avoided.

In the assembly of a fluid distribution manifold including bonded relief plates, the contact region 328 between plates 320 and 315 is the area between plates which touch or are connected by bonding agent during assembly. It is desirable to have a minimum amount of bonding metal. In order to use less bonding metal, it is desirable to have a surface finish quality exceeding the minimum threshold described above to avoid both gaps between plates as well as roughness features on the plates which would consume excess bonding metal in an uncontrolled way, making it difficult to consistently apply a minimum amount of bonding metal. Accordingly, the fluid distribution manifold can have first and second plates 315, 320 including a contact region 328 where the bonding agent is disposed with at least one of the first plate 315 and the second plate 320 including a mirrored surface finish 327 in the contact region 328.

Alternatively, the fluid distribution manifold can include several bonded plates. The mirrored surface finish can be present on any of the contact regions or the output face. In the case of a contact region between two plates, the mirror surface finish can exist on one or both of the contacting surfaces.

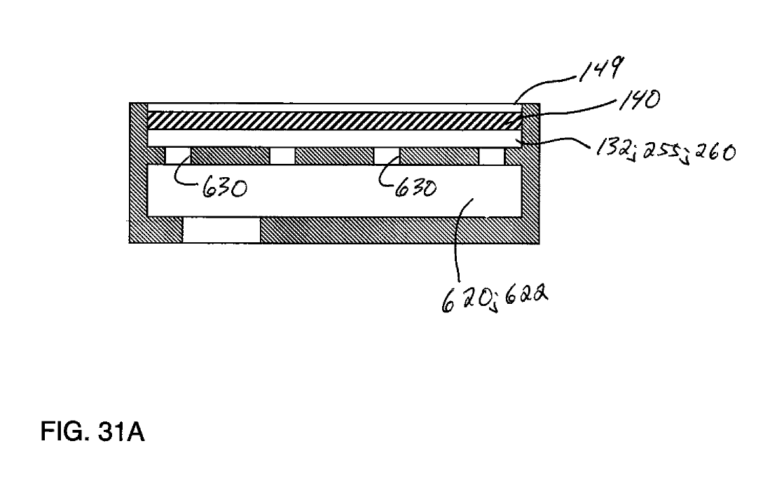

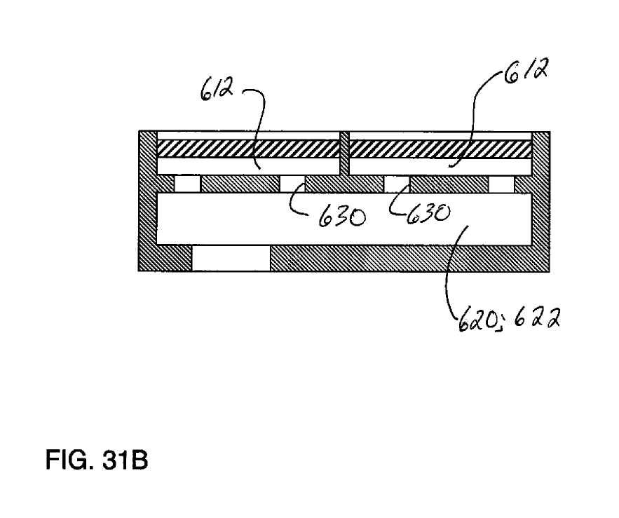

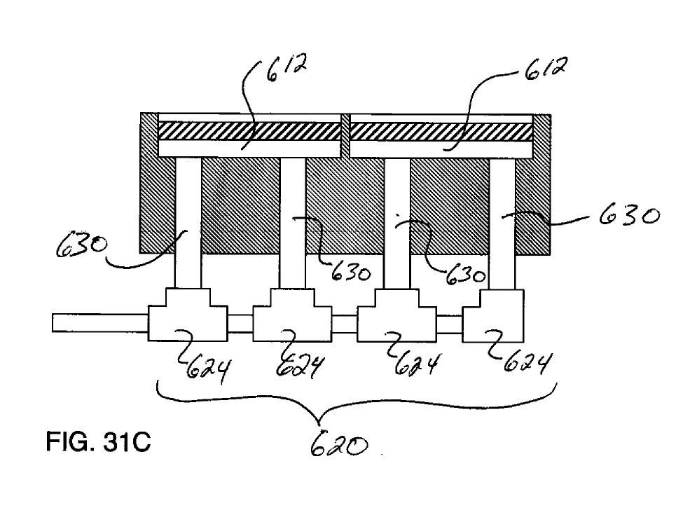

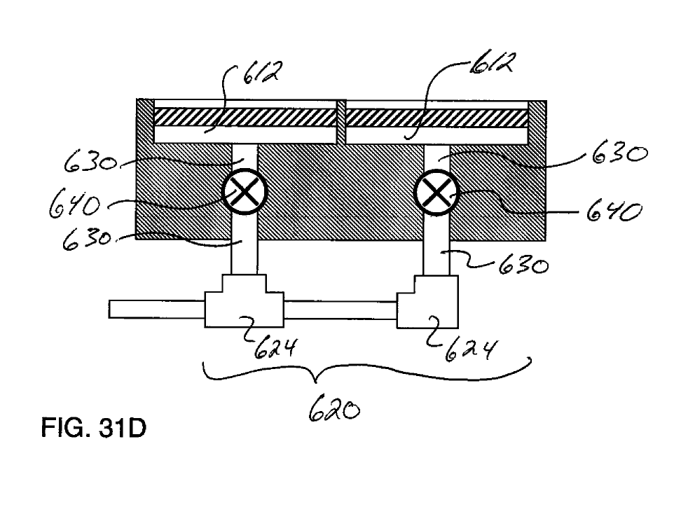

Referring to FIGS. 31A-31D, and back to FIGS. 1 through 28E, delivery head 10, also referred to as a fluid distribution manifold, supplies fluids, for example, gas, uniformly across the elongated slots, also referred to as output passages 149, at the output face of delivery head 10. A typical way to supply fluid uniformly is to have an elongated output face slot (also referred to as output passage 149) in fluid communication with a separate primary chamber 610, for example, elongated emissive channel 132 or directing channel recess 255. Primary chamber 610 typically runs approximately the length of the slot 149. The primary chamber 610 is connected to the slot 149 through flow restricting channels, for example, diffuser 140, and at the same time has low flow restriction along its length. The result is that fluid flows in the primary chamber 610 until its pressure is nearly constant along the chamber and then exits into the slot 149 through the flow restrictions in a uniform way. In general, restriction in lateral flow within the primary chamber 610 is a function of its cross sectional shape and area. Typically, the presence of lateral flow restrictions in primary chamber 610 is undesirable as they can lead to non-uniform flow exiting through slot 149.

Often constraints in the construction of a fluid distribution manifold limit the cross sectional dimensions of the primary chamber, which will in turn limit the length over which it can supply the output face slot 149. To minimize this effect, a fluid conveyance device, also referred to as ALD system 60, for thin film material deposition includes a fluid distribution manifold, also referred to as delivery head 10, that includes an output face 36 connected in fluid communication to a primary chamber 610. A secondary fluid source 620 is connected in fluid communication to the primary chamber 610 through a plurality of conveyance ports 630. The secondary fluid source 620, for example, secondary chamber 622, operates in a manner analogous to the primary chamber 610, permitting low resistance lateral flow of fluid along the secondary chamber 622 while supplying a uniform fluid flow to primary chamber 610. This acts to remove the effect of the restriction of lateral flow from the primary chamber 610 described above. As such, the conveyance ports 630 can be any fluid conduit that allows transfer between the secondary chamber 622 and primary chamber 610. The conveyance port 630 can be of any cross section, or any combinations of cross sections. While the conveyance ports 630 should normally have low resistance to flow, it can be useful to design the conveyance ports 630 to have a specific resistance to flow in order to modulate flow from the secondary fluid source 620 to primary chamber 610.

As shown in FIGS. 31A-31C, the primary chamber 610 can include a chamber that is common to at least some of the plurality of conveyance ports 630 of the secondary fluid source 620. In these embodiments, the fluid distribution manifold contains a relatively longer primary chamber 610 that is fed by more than one inlet from the secondary chamber 622. As such, even if primary chamber 610 does not provide a sufficiently low flow resistance in order to supply the entire length of the slot 149, it can be supplied locally from the secondary chamber 622. Additionally, if there are residual pressure differences along the primary chamber 610, the continuity of primary chamber 610 allows for some fluid flow to equalize pressures in the primary chamber 610.

Referring to FIG. 31B, alternatively, the primary chamber 610 can include a plurality of discrete primary chambers 612. Each of the plurality of discrete primary chambers 610 is in fluid communication with at least one of the plurality of conveyance ports 630 of the secondary fluid source 620.

The secondary fluid source 620 can include a monolithic fluid chamber affixed to the fluid distribution manifold (delivery head 10). When the fluid distribution manifold has a nearly rectangular cross section, the secondary chamber 620 can be an element that is similar in cross section and mounted directly any surface of the distribution manifold other that the output face. The secondary chamber 620 can have openings that match openings in the fluid distribution manifold, and can be permanently or temporarily attached to delivery head 10 using conventional sealing technology. For example, seals can be fabricated from rubber, oils, waxes, curable compounds, or bonding metals.

In addition, the secondary chamber can be monolithic and integrally formed with the fluid distribution manifold, as shown in FIGS. 31A and 31B. Thus, when the distribution manifold includes an assembly of relief patterned plates, the secondary chamber is composed of one or more fluid directing channels created from one or more relief plates added to the distribution manifold. These relief plates can be fabricated and assembled in the same manner as the relief plates that create the primary chamber and output faces. Alternatively, as the dimensions of the secondary chamber and the primary chamber are different when compared to each other, different assembly methods can be used. There may also be additional mechanical or cost reasons to assemble the secondary chamber and the primary chamber differently.

Referring to FIG. 31C, alternatively, the secondary fluid source 620 can include a fluid chamber 624 connected in fluid communication through a plurality of discrete conveyance channels 630 to the fluid distribution manifold 10. The discrete conveyance channels 630 can be any fluid conduits that are suitable for delivering fluid in this environment. For example, these conduits can be tubes of any useful cross sectional size and shape that are assembled to connect with the inlets to the distribution manifold either temporarily (removable) or permanently. Removable connectors include conventional fittings and flanges. Permanent connections include welding, brazing, adhesion, or press fitting. A portion of the conduits of a secondary chamber can also be constructed via casting or machining of a bulk material.

Referring to FIG. 31D, at least one of the conveyance ports 630 can include a device 640 configured to control the fluid flow through the associated conveyance port 630. When the fluid distribution manifold includes a secondary chamber 624 in fluid communication with more than one primary chamber 612, it can be useful to modulate the flow of fluid into one of the primary chambers 612 relative to the flow in another. It can also be desirable to supply a different fluid composition to one of the primary chambers 612 relative to the composition provided to another. The following system capabilities are thus enabled: (1) if a given distribution manifold is meant to coat several different widths of substrate, portions of the distribution manifold can be turned off so that only the width of the current substrate receives the active fluids; (2) if portions of a larger substrate need not be coated, portions of the distribution manifold can be turned off for areas where deposition is not desired; (3) if portions of a substrate are meant to receive an alternate deposition chemistry that other portions, portions of the distribution manifold can provide another fluid chemistry to the substrate.

In order to modulate the flow to one or more of the primary chambers 612, a valve system 640 located between the secondary chamber 620 and the primary chamber 610 can be used. The valve 640 can be any standard type of valve used to modulate fluid flow. When secondary chamber 620 is integral to the distribution manifold, the valve 640 can be an integral part of the manifold and can be formed by exploiting movable elements included in the construction of the manifold. The valves 640 can be controlled manually, or by remote actuators including, for example, pneumatic, electric, or electro pneumatic actuators.

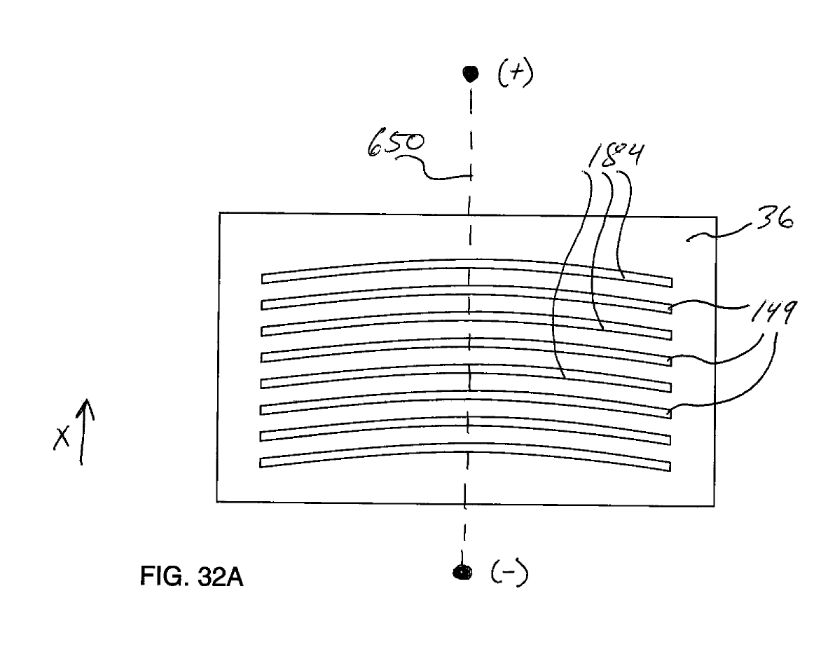

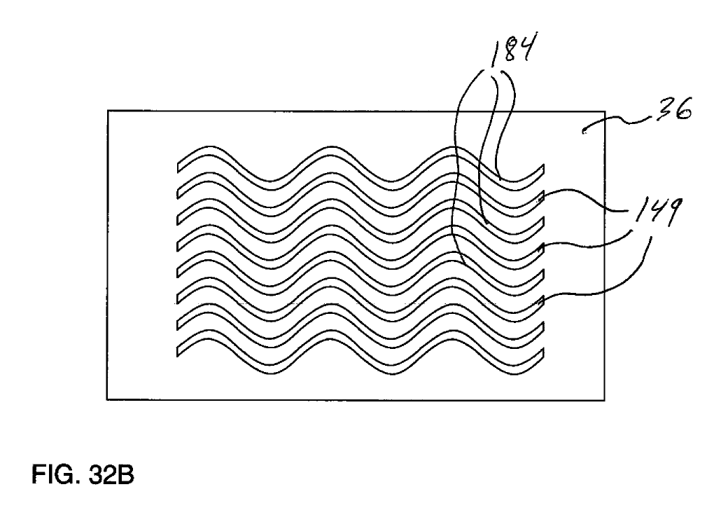

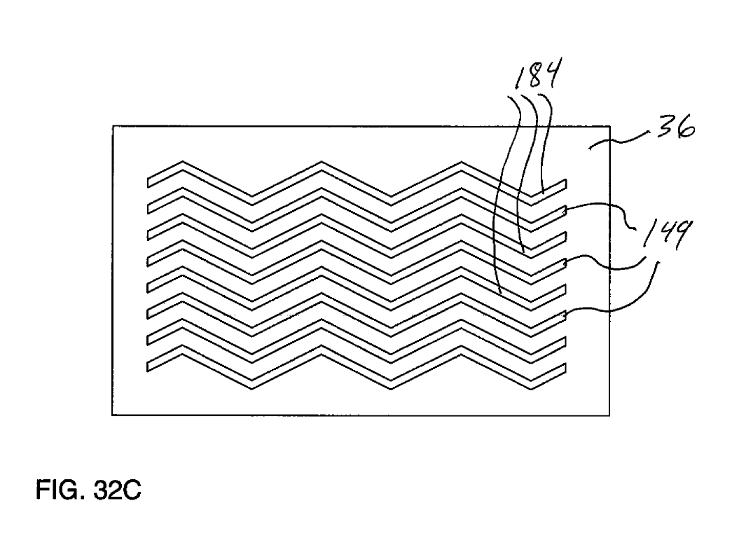

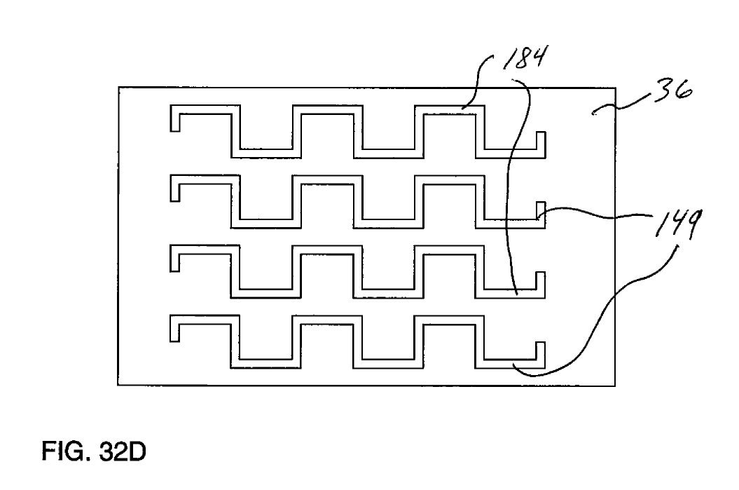

Referring to FIGS. 32A-32D, and back to FIGS. 1 through 28E, in the example embodiments described above, the layout for the output face 36; 148 of the distribution manifold 10 includes the elongated source slots 149 and elongated exhaust slots 184 typically exist in a configuration where the majority of slots are perpendicular to movement of the substrate in order to effect deposition. Additionally, slots can be present at the edge of the output face 36; 148, and parallel to the substrate transport to provide isolation of gases near the lateral edges of the moving substrates.

Referring to FIGS. 32A-32D, the fluid conveyance device (ALD deposition system 60) for thin film material deposition can include a substrate transport mechanism 54; 62 that causes a substrate 20; 66 to travel in a direction. Fluid distribution manifold 10 includes an output face 36; 148 that includes a plurality of elongated slots, for example, slots 149, 184, or combinations thereof. At least one of the elongated slots 149, 184, or combinations thereof, includes a portion that is non-perpendicular and non-parallel relative to the direction of substrate 20; 66 travel.

For example, referring back to FIG. 21, when substrate 20; 66 is moving in a direction x, elongated slots that are perpendicular to the substrate movement make an angle of 90 degrees with respect to x, while elongated slots that are parallel to the substrate movement make an angle of 0 degrees with respect to x. However, in any mechanical system there is, typically, some amount of variability with respect to angles in the system. Thus, non-perpendicular can be defined as any angle with respect to the substrate movement x that is less than 85 degrees, while non-parallel can be defined as any direction with respect to substrate movement x that is greater than 5 degrees. Therefore, when slots 149, 184, or combinations thereof are linear, the slots are disposed at an angle of greater than 5 degrees and less than 85 degrees from the direction of substrate motion. Non-linear slots also satisfy this condition when sufficient curvature is present.

When coating flexible substrates with the distribution manifold of the present invention, there is a different force exerted by the fluid when over the source slots as compared to that over the exhaust slots. This is a natural outcome of the fact that the fluid pressures are set up to drive fluid from the source to the exhaust slots. The resultant effect on the substrate is that the substrate will be forced away from the head to a higher degree over the source slots than over the exhaust slots. This in turn can lead to deformation of the substrate, which is undesirable since it leads to a non uniform height of flotation, and thus the potential for fluid mixing and contact between the substrate and the output face.

A flexible substrate can bend most easily when the bend in made over a linear shape, that is when the axis of the bend occurs only in one dimension. Thus, for a series of linear parallel slots, only the intrinsic beam strength of the substrate is resisting the force difference between slots, and therefore significant deformation of the substrate results.

Alternatively, when an attempt is made to bend a substrate over a non linear shape, that is a shape which extends in two dimensions, the effective beam strength of the substrate is much increased. This is because to accomplish a two dimensional bend, not only must the substrate bend directly over the non linear bend shape, but the attempt to cause a non linear bend leads to compression and tension in adjacent regions of the substrate. Since the substrate can be quite resistant to compressive or tensile forces, the result is a greatly increased effective beam strength. Thus, the use of non linear slots can allow substrates of higher flexibility to be handled without undesirable gas mixing or substrate contact with the output face. Therefore, slots 149, 184, or combinations thereof which are non-linear over their length can be particularly desirable for use in the distribution manifold.

As such, the fluid distribution manifold 10 of the conveyance system 60 can have at least a portion of one elongated slot including a radius of curvature, as shown in FIG. 32A. Any degree of non linearity can be useful to accomplish the increase in effective beam strength. The radius of curvature can be up to 10 meters to produce a beneficial effect. If a center line 650 is drawn through the center of the output face 36 extending in the direction of substrate motion x, positive positions on this line can be defined as positions going from the output face 36 in the direction of substrate travel x, while negative positions can be defined as positions going from the output face 36 in the opposite direction of substrate travel x. The radius can have a center point that is located at a negative or a positive position with respect to the center of the output face 36. The center point can also be offset in a direction other than that of the substrate travel x, so that the elongated slots are not symmetrically positioned on the output face 36.

For more flexible substrates requiring a larger increase in effective beam strength, smaller radii of curvature can be desirable. At some lower limit of radius, the slot may undergo too much change in angle relative to the substrate, thus requiring that the radius of curvature be variable along its length. As such, the fluid distribution manifold 10 of the conveyance system 60 can contain at least one portion of one elongated slot including multiple direction (or path) changes. This can take the form of an arbitrary pattern of direction changes along the slot, or of a slot with a periodic variation in radius of curvature. Periodic patterns can include or be combinations of a sine wave (FIG. 32B), a saw tooth (FIG. 32C), or square wave periodicity (FIG. 32D). Since an output face 36 includes many slots 149, 184, or combinations thereof, the slot shapes can be any combination of the above features, including the use of slots which are symmetric or mirror images of neighboring slots. Slots can also have different shapes depending upon their function as source slots 149 or exhaust slots 184, or based upon the type of gas composition that they supply.

The non-perpendicular, non-parallel portions of the elongate slots can include a maximum angle relative to the direction of substrate travel that is greater than or equal to 35 degrees. When slots 149 or 184 are located on a diagonal relative to the substrate motion, a beneficial effect can be obtained with some degree of non perpendicularity to the substrate motion. However, as the slots approach parallelism to the substrate motion, the number of ALD cycles experienced by the substrate as it moves over the deposition manifold decreases for a given length of manifold and a given slot spacing. Therefore, when slots 149, 184 are positioned diagonally, it is desirable to position the slots at an angle that is greater than 35 degrees relative to the direction of substrate motion, and more preferably at an angle that is greater than or equal to 45 degrees.

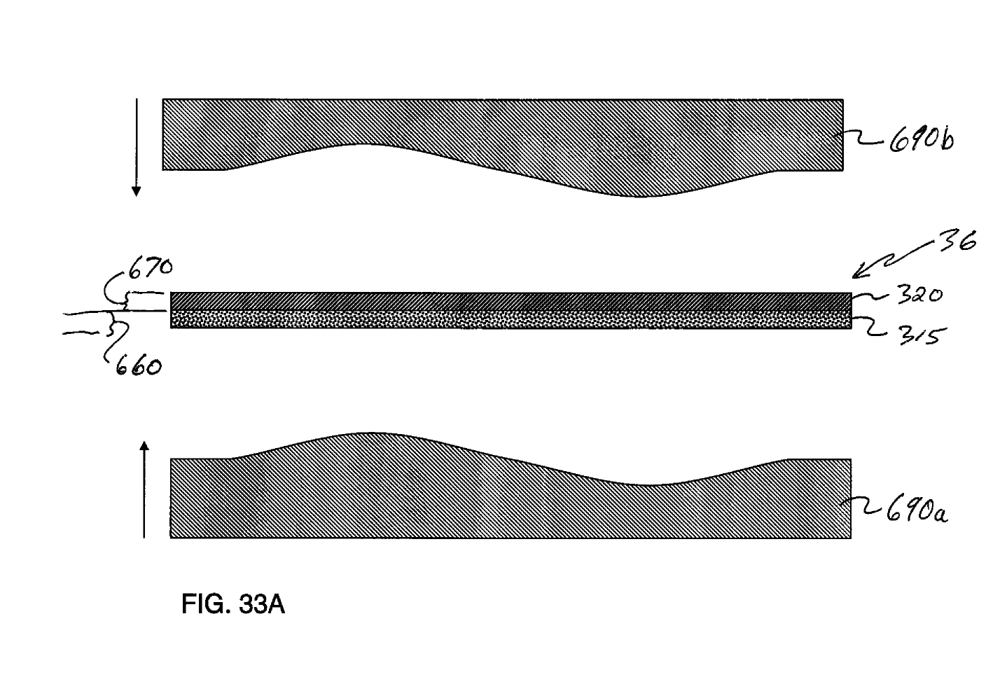

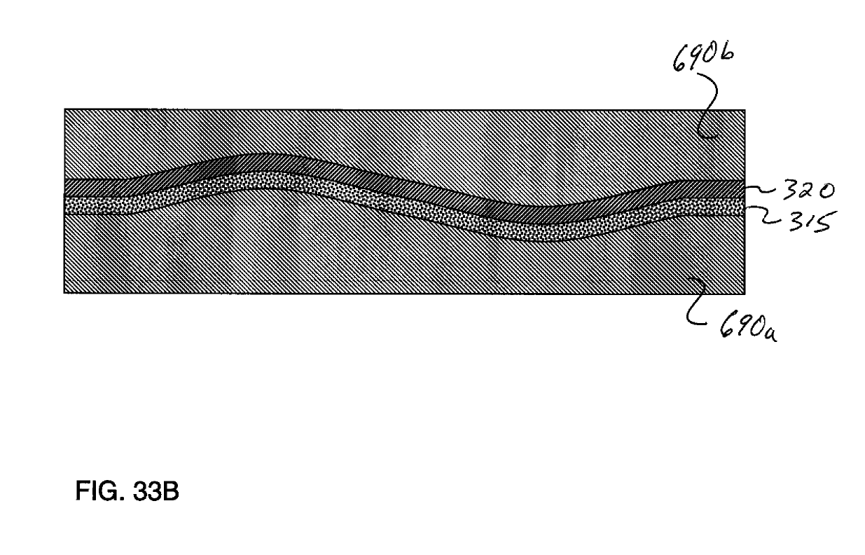

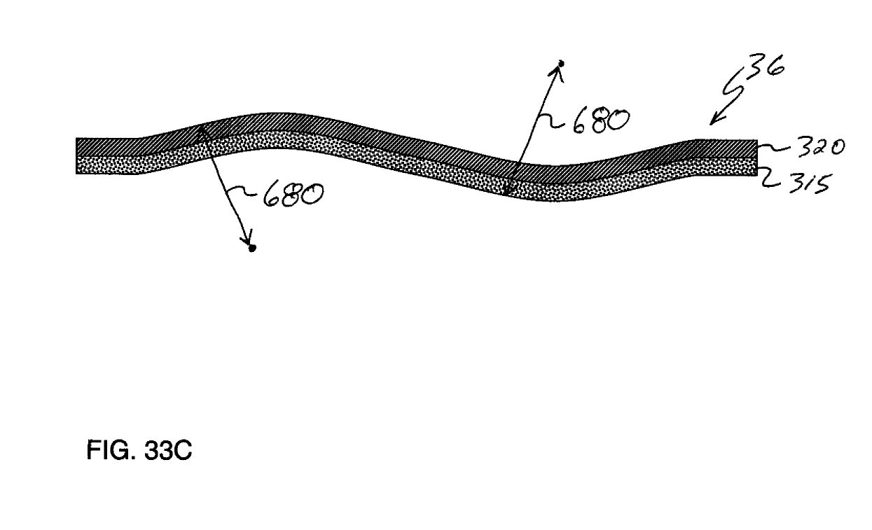

Referring to FIGS. 33A through 33C, and back to FIGS. 6 through 18, in some example embodiments it is desirable to have an output face that is not flat. As shown in FIG. 6, the output face 36 extends in the x and y directions and has no variation in the z direction. In FIG. 6, the x direction is perpendicular to substrate motion while the y direction is parallel to substrate motion. In the example embodiment shown in FIGS. 33A-33C, the output face 36 includes a variation in the z direction.

The use of a curved output face 36 can allow substrates of higher flexibility to be coated without undesirable gas mixing or substrate contact with the output face. The curvature of output face 36 can extend in either the x direction, the y direction, or both directions.

When coating flexible substrates with the distribution manifold of the present invention, there is a different force exerted by the fluid when over the source slots as compared to that over the exhaust slots. This is a natural outcome of the fact that the fluid pressures are set up to drive fluid from the source to the exhaust slots. The resultant effect on the substrate is that the substrate will be forced away from the head to a higher degree over the source slots than over the exhaust slots. This in turn can lead to deformation of the substrate, which is undesirable since it leads to a non uniform height of flotation, and thus the potential for fluid mixing and contact between the substrate and the output face.

A flexible substrate can bend most easily when the bend in made over a linear shape, that is when the axis of the bend occurs only in one dimension. Thus, for a series of linear parallel slots, only the intrinsic beam strength of the substrate is resisting the force difference between slots, and therefore significant deformation of the substrate results.

Curvature of the output face 36 along the x direction allows the substrate 20 being coated to be bent in two dimensions (the width and the height), and therefore increases the effective beam strength of the substrate 20. In order to create a two dimensional bend in the substrate 20, the substrate is bent directly over the non linear bend shape of the output face 36 which causes compression and tension in adjacent regions of the substrate 20. Since the substrate 20 can be quite resistant to compressive or tensile forces, this result is a greatly increased effective beam strength in the substrate 20.

Curvature of the output face 36 along the y direction allows easier control of the downward force of the substrate 20 on the output face 36 of the distribution manifold 10. When curvature extends in the y direction of the output face 36, substrate 20 tension can be used to control the downward force of the substrate 20 relative to the output face 36. In contrast, when output face 36 has no variation in the z direction, the downward force of the substrate 20 can only be controlled either using the weight of the substrate or an additional element that provides a force that acts on the substrate 20.

One conventional way to curve the output face 36 is to machine the plates of distribution manifold 10 such that they include variation in the z direction. However, this necessitates that the manifold plates be designed and constructed for any proposed profile of height variation, leading to an increased cost of manufacture of the distribution manifold.

When the distribution manifold 10 includes an assembly of patterned relief plates, these increased costs can be reduced or even avoided if the thickness of the plates in the z direction is such that the plates can be deformed to a desired profile during the assembly process. In this approach, a similar set of relief plates can be used to produce several distribution manifold height profiles in the z direction, simply by assembling them in the appropriate mold elements.

Again referring to FIGS. 33A-33C, fluid distribution manifold 10 includes a first plate 315 and a second plate 320. The first plate 315 includes a length dimension extending in the y direction and a width dimension extending in the x direction. The first plate 315 also includes a thickness 660 that allows the first plate 315 to be deformable (also referred to as compliant) over at least one of the length dimension extending in the y direction and the width dimension extending in the x direction of the first plate 315. In addition, the second plate 320 includes a length dimension extending in the y direction and a width dimension extending in the x direction. The second plate also includes a thickness 670 that allows the second plate 320 to be deformable (compliant) over at least one of the length dimension extending in the y direction and the width dimension extending in the x direction of the second plate 320. At least a portion of at least the first plate 315 and the second plate 320 define a relief pattern (for example relief pattern shown and described with reference to FIGS. 12A and 12B) that defines a fluid flow directing path. The first plate 315 and the second plate 320 are bonded together to form a non-planar shape in a height dimension extending in the z direction along at least one of the length dimension and the width dimension of the plates 315, 320.

The thickness suitable to allow the plates to be compliant depends upon the material of construction and the radius of curvature that is contemplated for a particular embodiment. Typically, any thickness can be used as long as the assembly process, for example, the plate bonding method, does not produce unacceptable distortion or structural failure in either or both plates. For example, when plates 315, 320 are constructed of metals including steel, stainless steel, aluminum, copper, brass, nickel, or titanium, generally, a plate thicknesses of less than 0.5 inches, and more preferably less than 0.2 inches are desired. For organic materials such as plastics and rubbers, plate thicknesses of less than 1 inch, and more preferably less than 0.5 inches are desired.

The non-planar shape of plates 315, 320 can include a radius of curvature 680. The curvature can have a line axis, indicating that curvature traces a portion of the surface of a cylinder. The axis can be in either the x or y directions, or in a direction that is a combination of x and y directions. The axis can also have some direction in the z direction, so that the maximum height of the curved surface is not constant along the output face. The radius of curvature can be up to 10 meters and still produce a beneficial effect. The axis can be above or below the output face resulting in a curvature that is convex or concave, respectively.

Alternatively, the curvature can have a point axis resulting in a curvature that traces a portion of the surface of a sphere. The point axis can be at any position above or below the output face resulting in a curvature that is convex or concave, respectively. The radius of curvature can be up to 10 meters and still produce a beneficial effect.

The output face 36 of the distribution manifold can include a periodic variation in height. This can take the form of an arbitrary pattern of direction changes, or a periodic variation in radius of curvature in the z direction. Periodic patterns can be a sine wave or a combination of sine waves that are capable of producing any periodic variation. Variations in radius of curvature can occur in both x and y directions simultaneously, leading to bumps or modes on the output face 36.

The distribution manifold 10 can be manufactured by bonding the first plate 315 and the second plate 320 together using a fixture that produces a non-planar shape in a height dimension (z direction) of the first plate 315 and the second plate 320. For example, the first plate 315 and the second plate 320 can be bonded together using a fixture that includes retaining the first plate 315 and the second plate 320 in a mold 690. In this fixture configuration, mold 690 includes a first mold half 690a and a second mold half 690b that include the height variation in its profile with the second mold half having a variation that is substantially the inverse of the first mold half.

A series of flat relief plates 315, 320 are placed between the mold halves. The mold halves are closed applying sufficient pressure to cause the relief plates to conform to the shape of the mold halves, as shown in FIG. 33B. A fixing element is then applied to cause bonding of the plates. For example, the fixing element can include one or a combination of heat, pressure, acoustic energy, or any other force that activates an adhesive or bonding agent previously disposed between the plates. The bonding action can also come from an intrinsic property of the relief plates. For example, if plates are pressed in a mold followed by current passage through the plate assembly, local heating can produce welds between the plates without the need for an extrinsic bonding agent.

Bonding of the first plate and the second plate can also be accomplished using a fixture that causes the first plate and the second plate to move through a set of rollers. For example, a series of rollers disposed along a non linear path can cause the relief plate assembly to adopt a particular curvature as the plate assembly passes though the rollers. The rollers can configured to simultaneously provide heat, pressure, acoustic energy, or another fixing force that causes the plates to bond together. The rollers can be movable during the head assembly by manual, remote, or computer controlled devices so that a desired variation in radius of curvature is produced. The rollers can also have a patterned surface profile that produces a periodic pattern of height variations in the finished distribution manifold.

As described above, the bonding process involves assembling the plates to be bonded followed by application of at least heat, or pressure, or a combination of heat and pressure. The heat can be applied by resistive, inductive, convective, radiative, or flame heating. It is often desirable to control the atmosphere of the bonding process to reduce oxidation of the metal components. Processes can occur at any pressure ranging from greater than atmospheric pressure to high vacuum processes. The composition of the gases in contact with the materials to be bonded should be largely devoid of oxygen, and may advantageously contain nitrogen, hydrogen, argon or other inert gases or reducing gases.

Regardless of how the distribution manifold is manufactured, one advantage of this example embodiment of the present invention is that while the individual plates can have sufficient flexibility to be assembled using this technique, once bonded, the overall strength of the distribution manifold is increased due to the cooperation between the plates.

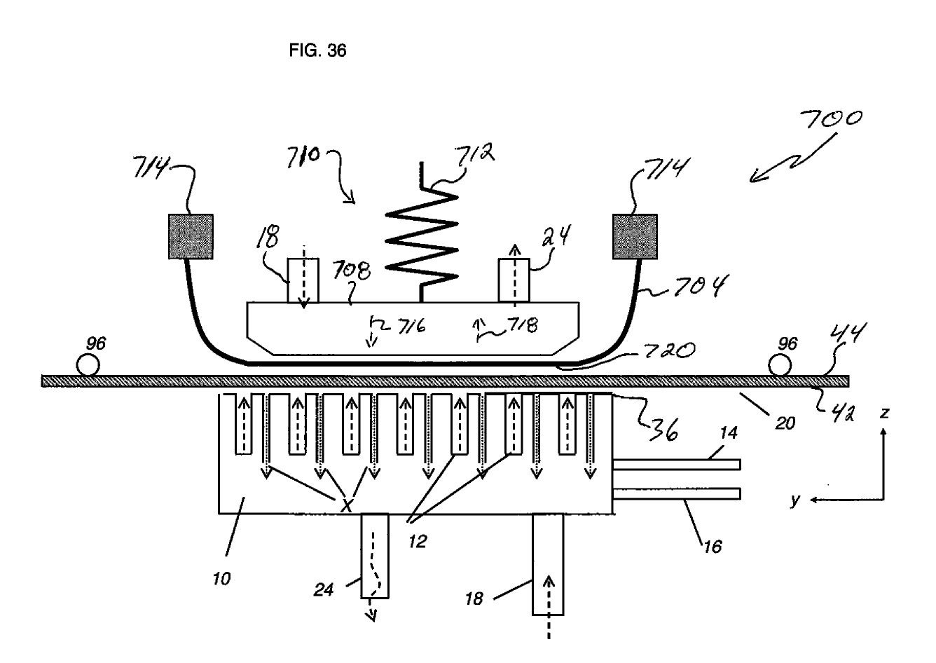

Referring to FIGS. 36-38, and back to FIGS. 3 and 6 through 18, as described above, when coating flexible substrates with the distribution manifold of the present invention, there is a different force exerted by the fluid over the source slots as compared to that over the exhaust slots. This is a natural outcome of the fact that the fluid pressures are set up to drive fluid from the source to the exhaust slots. The resultant effect on the substrate is that the substrate may be forced away from the head (to a higher degree over the source slots than over the exhaust slots) or into contact with the output face of the delivery head (to a higher degree over the exhaust slots than over the source slots). This in turn may lead to deformation of the substrate, which is undesirable since it leads to a non uniform height of flotation, and thus the potential for fluid mixing and contact between the substrate and the output face.

One useful way to mitigate the effect of this non-uniform force on the substrate is to provide support to the opposite side of the substrate (side of the substrate not facing the delivery head). Supporting the substrate provides enough force so that the intrinsic beam strength of the substrate can reduce the likelihood or even prevent the substrate from significantly changing shape, especially in the z direction (height), which may lead to poor gas isolation, cross contamination or mixing of the gasses, or possible contact of the substrate to the output face of the distribution manifold.

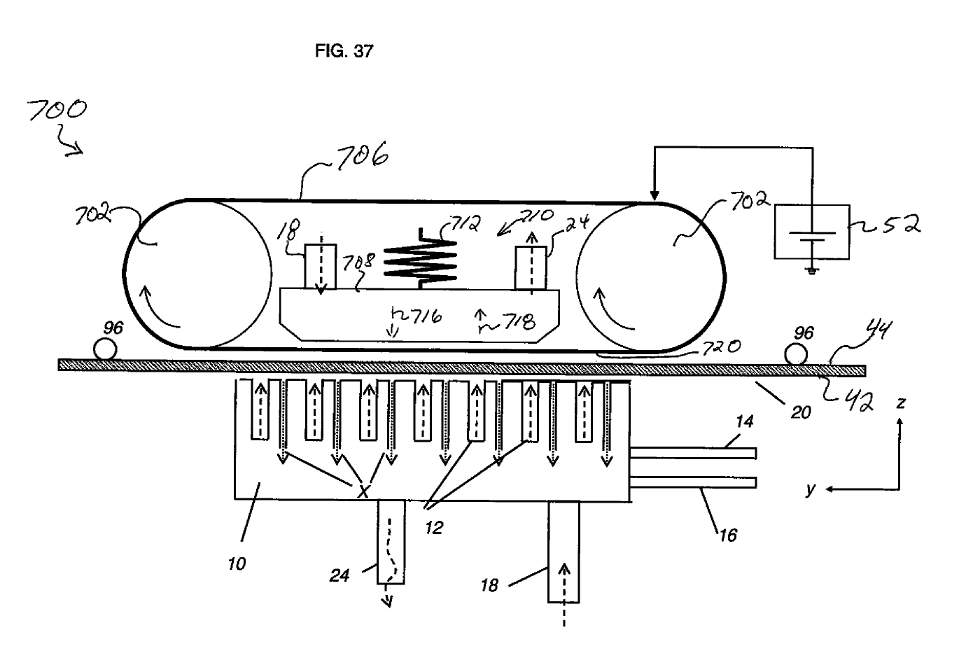

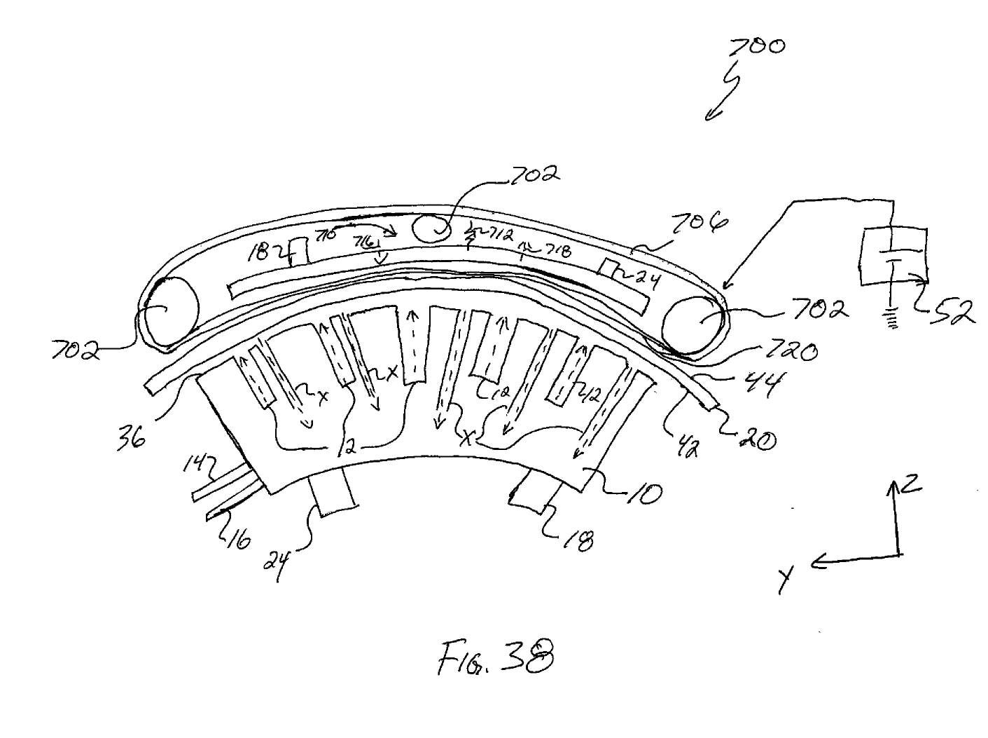

In this example embodiment of the present invention, fluid conveyance system 60 includes a fluid distribution manifold 10 and a substrate transport mechanism 700. As described above, fluid distribution manifold 10 includes an output face 36 that includes a plurality of elongated slots 149, 184. The output face 36 of the fluid distribution manifold 10 is positioned opposite a first surface 42 of substrate 20 such that the elongated slots 149, 184 face the first surface 42 of the substrate 20 and are positioned proximate to the first surface 42 of the substrate 20. The substrate transport mechanism 700 causes substrate 20 to travels in a direction (for example, the y direction). The substrate transport mechanism 700 includes a flexible support 704 (as shown in FIG. 36) or 706 (as shown FIGS. 37 and 38). Flexible support 704, 706 contacts a second surface 44 of the substrate 20 in a region that is proximate to the output face 36 of the fluid distribution manifold 10.

As shown in FIG. 36, flexible support 704 is fixed and affixed to a set of conventional support mounts 714. As shown in FIGS. 37 and 38, flexible support 706 is moveable. When flexible support 706 is moveable, flexible support 706 can be an endless belt that is driven around a set of rollers 702, at least one of which can be driven using transport motor 52.

Flexible support 706 is also conformable such that it can be contoured into a non-planer shape (shown in FIG. 38) in order to accommodate a contoured delivery head 10. As support 704 is also flexible, support 704 can also be contoured. Flexible support 704 can be made from any suitable material, for example, metal or plastic, that provides the desired amount of flexibility. Flexible support 706 is typically made from a suitable belt material, for example, a polyimide material, a metal material, or be coated with a tacky material that helps the substrate maintain contact with a surface 720 of flexible support 704, 706.

Substrate 20 can be either a web or a sheet. In addition to creating and maintaining spacing between output face 36 of delivery head 10 and substrate 10, substrate transport mechanism 700 can extended in either an upstream direction, a downstream direction, or in both directions relative to the delivery head 10 and provide additional substrate transport function to the ALD system 60.

Optionally, flexible support 704, 706 can also provide a mechanical pressure to the second surface 44 of the substrate 20. For example, a fluid pressure source 730 can be positioned to provide a fluid under pressure through conduit 18 to the region of the flexible support 704, 706 that acts on the second surface 44 of the substrate 20. The pressure of the fluid can be either positive 716 or negative 718 as along as the pressure 716, 718 is sufficient to position the substrate 20 relative to the output face 36 of the fluid distribution manifold 10. When pressure 716, 718 is provided by flexible support 704, 706, flexible support 704, 706 can include apertures (also referred to as perforations) that provide (or apply) either the positive pressure 716 of the negative pressure 718 to second surface 44 of substrate 20. Other configurations are permitted. For example, the pressure 716, 718 can be provide around flexible support 704, 706.

When the pressure provided by the fluid pressure source is a positive pressure 716, it pushes the substrate 20 toward the output face 36 of the fluid distribution manifold 10. When the pressure provided by the fluid pressure source is a negative pressure 718, it pulls (also referred to as draws) the substrate 20 away from the output face 36 of the fluid distribution manifold 10 and toward the flexible support 704, 706. In either configuration a relatively constant spacing between the substrate 20 and the distribution manifold 10 can be achieved and maintained.

As described above, each of the plurality of elongated slots 149, 184 are connected in fluid communication to a corresponding fluid source that is associated with delivery head 10. A first corresponding fluid source associated with delivery head 10 provides a gas at a pressure sufficient to cause the gas to move through the elongated slot 149 and into the area between the output face 36 and the first surface 42 of the substrate 20. A second corresponding fluid source associated with delivery head 10 can provide a fluid at a positive back pressure sufficient to allow gas to flow away from the area between the output face 36 and the first surface 42 of the substrate 20 and toward the elongated slot 184. When the pressure provided by the fluid pressure source 730 is a positive pressure 716, the magnitude of the pressure 716 is typically greater than the magnitude of the positive back pressure provided by the second corresponding fluid source associated with delivery head 10.

The mechanical pressure that can be provided by flexible support 704, 706 to the second surface 44 of the substrate 20 can include other types of mechanical pressure. For example, the mechanical pressure can be provided to second surface 44 of substrate 20 by using a flexible support 704, 706 that is spring loaded through a support device 708 using a load device mechanism 712. Load device mechanism 712 can includes a spring and a load distribution mechanism to evenly applied the mechanical force to flexible support 704, 706 or to apply sufficient beam strength or increase the beam strength of flexible support 704, 706. Alternatively, flexible support 704, 706 can be placed in a constrained position such that the flexible support 704, 706 itself exerts the spring loaded force on the second surface 44 of substrate 20 to create the beam strength in substrate 20 necessary to create and maintain constant spacing relative to output face 36 of delivery head 10.

The mechanical pressure that can be provided by flexible support 704, 706 to the second surface 44 of the substrate 20 can include other types of mechanical pressure. For example, transport mechanism 700 can include a mechanism that creates a static charge differential between flexible support 704, 706 and the substrate 20 that induces a static electrical force that draws the substrate 20 away from the output face 36 of the fluid distribution manifold 10 and toward the flexible support 704, 706.

Support device 708 can also be heated in order to provide heat to flexible support 704, 706, that ultimately heats substrate 20. Heating substrate 20 helps to maintain a desired temperature on the second side 44 of the substrate 20, or on the substrate 20 as a whole during ALD deposition. Alternatively, heating support device 708 can help to maintain a desired temperature in the area around the substrate 20 during ALD deposition.

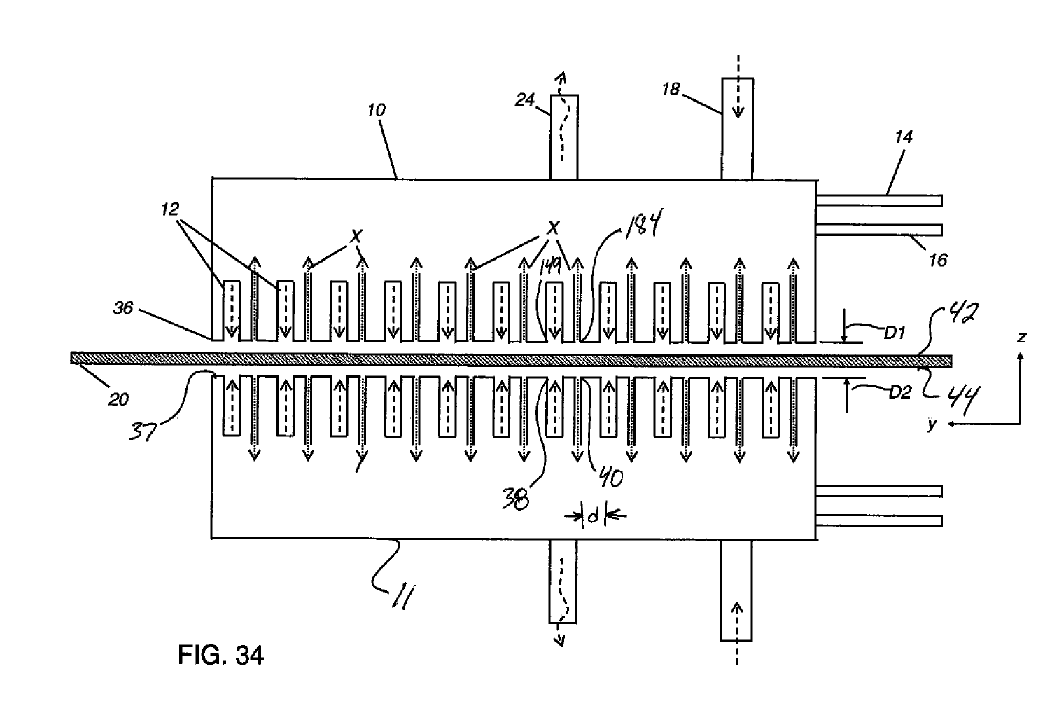

Referring to FIG. 34, and back to FIGS. 3 and 6 through 18, as described above, when coating flexible substrates with the distribution manifold of the present invention, there is a different force exerted by the fluid when over the source slots as compared to that over the exhaust slots. This is a natural outcome of the fact that the fluid pressures are set up to drive fluid from the source to the exhaust slots. The resultant effect on the substrate is that the substrate may be forced away from the head to a higher degree over the source slots than over the exhaust slots. This in turn can lead to deformation of the substrate, which is undesirable since it leads to a non uniform height of flotation, and thus the potential for fluid mixing and contact between the substrate and the output face.

One useful way to mitigate the effect of this non-uniform force on the substrate is to apply a similar non-uniform force on the opposite side of the substrate. The opposing non-uniform force should be similar in magnitude and spatial location to the force provided by the fluid distribution manifold, so that there is only a small remaining net local force acting on specific areas of the substrate. This remaining force is small enough so that the intrinsic beam strength of the substrate can reduce the likelihood or even prevent the substrate from significantly changing shape, especially in the z direction (height), that may lead to poor gas isolation and possible contact of the substrate to the output face of the distribution manifold.

Again referring FIG. 34, one example embodiment of this aspect of the present invention includes a fluid conveyance system 60 for thin film material deposition that includes a first fluid distribution manifold 10 and a second fluid distribution manifold 11. Distribution manifold 10 including an output face 36 that includes a plurality of elongated slots 149, 184. The plurality of elongated slots 149, 184 including a source slot 149 and an exhaust slot 184.

In order to create the opposing force that is similar in magnitude and direction, described above, the second fluid distribution manifold 11 includes an output face 37 that is similar to output face 36. Output face 37 includes a plurality of openings 38, 40. The plurality of openings 38, 40 includes a source opening 38 and an exhaust opening 40. The second fluid distribution manifold 11 is positioned spaced apart from and opposite the first fluid distribution manifold 10 such that the source opening 38 of the output face 37 of the second fluid distribution manifold 11 mirrors the source slot 149 of the output face 36 of the first fluid distribution manifold 149. Additionally, the exhaust opening 40 of the output face 37 of the second fluid distribution manifold 11 mirrors the exhaust slot 184 of the output face 36 of the first fluid distribution manifold 10.

In operation, a first side 42 of a substrate 20 is in closest proximity to the output face 36 of the first distribution manifold 10, while a second side 44 of the substrate 20 is in closest proximity to the output face 37 of the second distribution manifold 11. As described above, the slots 149, 184 of output face 36 and the openings 38, 40 of output face 37 can provide source or exhaust functions. Slots or openings of any output face that provide a source function insert fluid into the region between that output face and the corresponding substrate side. Slots or openings of any output face that provide an exhaust function withdraw fluid from the region between that output face and the corresponding substrate side.

The mirror positioning of manifold 10 and manifold 11 helps ensure that a given opening on the output face 37 of the second distribution manifold 11 is located in a direction approximately normal to a slot located on the first output face 36 of first distribution manifold 10. In operation, output face 37 and output face 36 are typically parallel to each other and the normal direction is in the z direction. Additionally, the same given opening provides the same function (either source or exhaust) as that of the slot that is located on the first output face 36 opposite the given opening. If the distance between adjacent slots on an output face is d, the tolerance of alignment between openings on the first and second distribution manifolds should be less that 50% of d, preferably less than 25% of d.

The fluid conveyance system 60 can include a substrate transport mechanism, for example, subsystem 54, that causes the substrate 20 to travel in a direction between the first fluid distribution manifold 10 and the second fluid distribution manifold 11. The substrate transport mechanism is configured to move the substrate 20 in a direction approximately parallel to the output faces 36, 37 of the fluid distribution manifolds 10, 11. The movement can be of a constant or varying velocity, or can involve variations in direction to produce reciprocation. Movement can be accomplished using, for example, motorized rollers 52.

The distance D1 between the substrate 20 and the first fluid distribution manifold 10 is typically substantially the same as the distance D2 between the substrate 20 and the second fluid distribution manifold 11. In this sense, distances D1 and D2 are substantially the same when the distances are within a factor of 2, or more preferably, within a factor of 1.5 of each other.

The plurality of openings 38, 40 of the second fluid distribution manifold 11 can include various shapes, for example, slots or holes. The first distribution manifold 10 is likely to have elongated slot for openings on its output face because this provides the most uniform delivery of fluid to and from the output face 36. The corresponding openings in the second distribution head 11 can also have slot features corresponding to source and exhaust regions. Alternatively, the openings in the second distribution head 11 can be hole features of any suitable shape. As the condition of providing a matching force on the second side of the substrate is not an exact condition, the matching force need only be sufficient to prevent deleterious deformation of the substrate. Therefore, a series of holes, for example, in the second distribution head 11 that are aligned across from a slot in the first distribution head 10 can be sufficient to reasonably match forces on the substrate 20 while allowing the second distribution head 11 to be simpler and fabricated at a lower cost.

As described above, the elongated slots on the output face 36 of the first distribution manifold 10 can be linear or curved. These slots can contain a variety of shapes including periodic variations such as sine patterns, sawtooth patterns, or square wave patterns. The openings on the second distribution head 11 can optionally have a similar shape to the corresponding slots on first distribution manifold 10.

In this example embodiment of the invention, the first fluid distribution manifold 10 and the second fluid distribution manifold 11 of the conveyance system 60 can both be ALD fluid manifolds. In example embodiments where the second distribution manifold 11 is operated to provide or run with non-reactive gases, this configuration ensures that the forces originating from the second fluid distribution manifold 11 will sufficiently match those being provided by the first fluid distribution manifold 10. In other example embodiments, the second fluid distribution manifold 11 can be configured to provide a set of reactive gases capable of producing an ALD deposition. In this configuration, both sides 42, 44 of substrate 20 can be simultaneously coated with films of the same or different compositions.

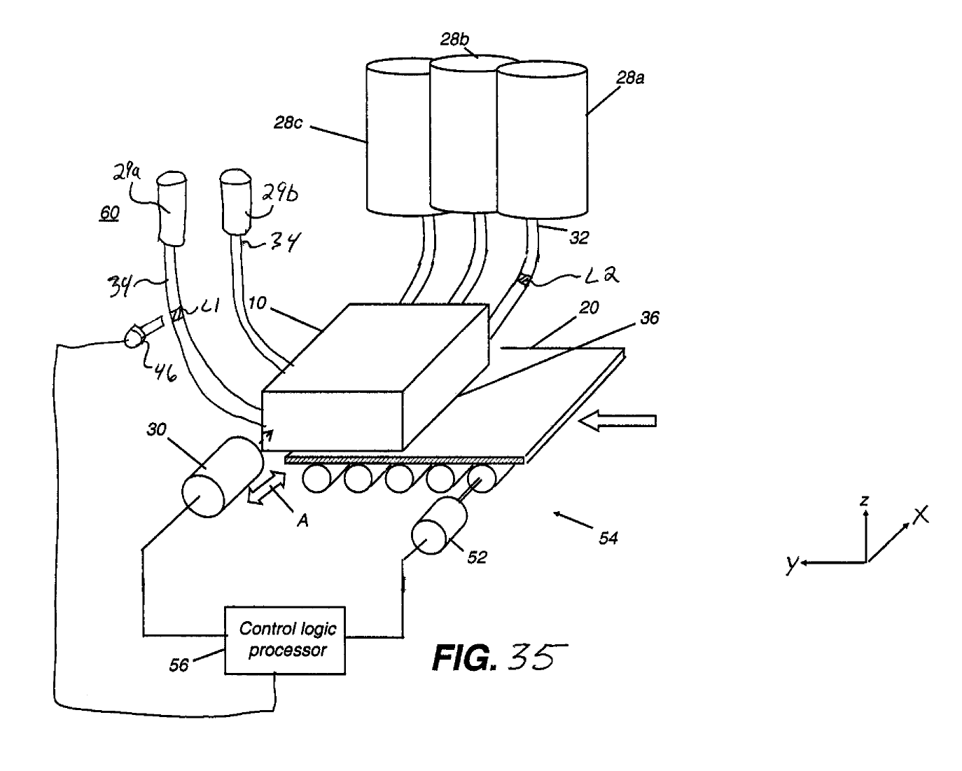

Referring to FIG. 35, and back to FIGS. 1 through 28E, in some example embodiments of the present invention, it is desirable to monitor one or more of the gases being delivered to or removed from the substrate 20. In one example embodiment of this aspect of the present invention, a fluid conveyance system 60 for thin film material deposition includes a fluid distribution manifold 10, a gas source, for example, gas supply 28, and gas receiving chamber 29a or 29b. as described above, the fluid distribution manifold 10 includes an output face 36 that includes a plurality of elongated slots 149, 184. The plurality of elongated slots includes a source slot 149 and an exhaust slot 184. The gas source 28 is in fluid communication with the source slot 149 and is configured to provide a gas to the output face 36 of the distribution manifold 10. A gas receiving chamber 29a or 29b is in fluid communication with the exhaust slot 184 and is configured to collect the gas provided to the output face 36 of the distribution manifold 10 through the exhaust slot 184. A sensor 46 is positioned to sense a parameter of the gas traveling from the gas source 28 to the gas receiving chamber 29. Controller 56 is connected in electrical communication with the sensor 46 and is configured to modify an operating parameter of the conveyance system 60 based on data received from the sensor 46.

Gas leaving the gas source 28 travels through an external conduit 32 and then through internal conduits within the fluid distribution manifold (described above) before arriving at the output face 36 through source slots 149. Gas leaving the output face 36 travels through the exhaust slots 184, through internal conduits within the fluid distribution manifold and through external conduits 34 before arriving at the gas receiving chamber 29. The gas source 28 can be any source of gas at higher pressure than the pressure of the conduits in order to supply gas to the output face 36. The gas receiving chamber 29 can be any gas chamber at lower pressure than the pressure of the conduits in order to remove the gas from the output face 36.

The sensor 46 can be positioned at various locations of the system 60. For example, the sensor 46 can be positioned between the exhaust slot 184 and the gas receiving chamber 29 as exemplified by position L1 in FIG. 35. In this embodiment, the sensor 46 can be included in the distribution manifold 10, the conduit system 34, the gas receiving chamber 29, or in more than one of these locations.

The sensor 46 can be positioned between the source slot 149 and the gas source 28 as exemplified by position L2 in FIG. 35. In this embodiment, the sensor 46 can be included in the distribution manifold 10, the conduit system 32, the gas supply chamber 28, or in more than one of these locations.

The sensor 46 can also be positioned at the output face 36 of the distribution manifold 10 as exemplified by position L3 shown in FIG. 3. In this configuration, the sensor 46 is preferably positioned between the source slot 149 and the exhaust slot 184.

The sensor 46 can be of the type that measures at least one of a pressure, a flow rate, a chemical property, and an optical property of the gas. When sensor 46 measures pressure, the pressure can be measured using any technology for pressure measurement. These include, for example, capacitive, electromagnetic, piezoelectric, optical, potentiometric, resonant, or thermal pressure sensing devices. Flow rate can also measured using any conventional technique, for example, the techniques described in “Flow Measurement” by Béla G. Lipták (CRC Press, 1993 ISBN 080198386X, 9780801983863).

Chemical properties can be measured to identify reactive precursors, reactive products, or contaminants in the system. Any conventional sensor for sensing chemical identities and properties can be used. Examples of sensing operations include: the identification of the precursor from a given source gas channel exiting into the exhaust of an alternate source gas channel, indicative of excessive mixing of reactants at the output face; the identification of the reaction products of two different source gases exiting in an exhaust channel, indicative of excessive mixing of reactants at the output face; and the presence of excessive contaminants, for example, oxygen or carbon dioxide, in an exhaust channel which can be indicative of air entrainment near the output face.

Optical properties of the gas can be used because optical measurement can be very rapid, relatively easy to implement, and provide a long sensor lifetime. Optical properties such as light scattering or attenuation can be used to identify the formation of particulates indicative of excessive component mixing at the output face. Alternatively, spectroscopic properties can be used to identify chemical elements in a flow stream. These can be sensed in ultraviolet, visible, or infrared wavelengths.

As described above, the sensor 46 is connected to controller 56. The controller 56 measures process values, of which at least one is the sensor output, and controls operating parameters as a function of the process values. The controller can be electronic or mechanical. Operating parameters are typically any controllable input to the fluid conveyance system 60 intended to have an effect on the operation of the system 60. For example, the operating parameters can include an input gas flow that can be modified by the controller 56.

The response to a sensor input can be direct or reverse. For example, a pressure reading indicating faulty system performance can result in a decrease or shutoff of gas flows in order to prevent emission or venting of reactive gases. Alternatively, it can result in an increase of gas flow in order to attempt to bring the system back into control.

As described above, the system can include a substrate transport mechanism, for example, subsystem 54, that causes the substrate 20 to travel in a direction relative to the fluid distribution manifold 10. The controller 56 can modify movement of the substrate 20 by adjusting an operating parameter of the substrate transport mechanism 54 in response to a sensor reading. Typically, these types of operating parameters include substrate speed, substrate tension, and substrate angle relative to the output face.

The controller 56 can also modify the relative position of the substrate transport mechanism 54 and the distribution manifold 10 by adjusting an operating parameter of the system. In this embodiment, at least one of the substrate transport mechanism 54 and the fluid distribution manifold 10 can include a mechanism that allows movement in a direction substantially normal to the output face 36 in the z direction. This mechanism can operate by electric, pneumatic, or electro-pneumatic actuation devices. The modification of the relative position of the substrate 20 and the fluid distribution manifold 10 can be accompanied by any other system parameter changes if desired.

The invention has been described in detail with particular reference to certain example embodiments thereof, but it will be understood that variations and modifications can be effected within the scope of the invention as described above, and as noted in the appended claims, by a person of ordinary skill in the art without departing from the scope of the invention.

### PARTS LIST

10 delivery head, fluid distribution manifold
11 fluid distribution manifold
12 output channel
14, 16, 18 gas inlet conduit
20 substrate
22 exhaust channel
24 exhaust port conduit
28a, 28b, 28c gas supply
29a, 29b gas receiving chamber
30 actuator
32 supply lines
34 conduit
36 output face
38, 40 opening
42 first side
44 second side
46 sensor
50 chamber
52 transport motor
54 transport subsystem
56 control logic processor
60 system
62 web conveyor
64 delivery head transport
66 web substrate
70 system
74 substrate support
90 directing channel for precursor material
92 directing channel for purge gas
96 substrate support
98 gas fluid bearing
100 connection plate
102 directing chamber
104 input port
110 gas chamber plate
112, 113, 115 supply chamber
114, 116 exhaust chamber
120 gas direction plate
122 directing channel for precursor material
123 exhaust directing channel
130 base plate
132 elongated emissive channel
134 elongated exhaust channel
140 gas diffuser plate assembly
142 nozzle plate
143 gas conduit
146 gas diffuser plate
147 output passages
148 output face plate
149 output passages
150 delivery assembly
154 elongated exhaust channel
170 spring
180 sequential first exhaust slots
182 slots
184 exhaust slots
200 flat prototype plate
220 relief containing prototype plate
230 prototype plate containing relief patterns on both sides.
215, 225, 235, 245 assembled plate unit
250 raised flat area of plate
255 directing channel recess
260 diffuser region on plate
265 cylindrical post
270 square post
275 arbitrary shaped post
300 machined block
305 supply lines in machined block
310 channels
315 first plate for horizontal diffuser assembly
318 metal bonding agent
320 second plate for horizontal diffuser assembly
322 fluid flow direction
325 diffuser area on horizontal plate
330 gas supply
335 diffused gas
327 mirrored surface finish
328 contact region
350 vertical plate assembly end plates
360 supply holes
365 typical plate outline
370 vertical plate to connect supply line #2 to output face
375 vertical plate to connect supply line #5 to output face
380 vertical plate to connect supply line #4 to output face
385 vertical plate to connect supply line #10 to output face
390 vertical plate to connect supply line #7 to output face
395 vertical plate to connect supply line #8 to output face
405 recess for delivery channel on plate
410 diffuser area on plate
420 raised area in diffuser discrete channel
430 slots in diffuser discrete channel
450 double sided relief plate
455 seal plate with lip
460 lip on seal plate
465 diffuser area
500 step of fabricating plates
502 applying adhesive material to mating surfaces
504 mounting plates on aligning structure
506 applying pressure and head to cure
508 grinding and polishing active surfaces
600 cleaning
610 primary chamber
612 discrete primary chambers
620 secondary fluid source
622 secondary chamber
624 fluid chamber
630 conveyance port
640 valve
650 center line
660, 670 thickness
680 curvature
690 mold
700 substrate transport mechanism
702 substrate support roller
704 flexible support fixed
706 flexible support moveable
708 support device
710 support mechanism
712 device load mechanism
714 support mount
716 positive pressure
718 negative pressure
720 surface
A arrow
D distance
E exhaust plate
F1, F2, F3, F4 gas flow
I third inert gaseous material
M second reactant gaseous material
O first reactant gaseous material
P purge plate
R reactant plate
S separator plate
X arrow
L1, L2, L3 position

1. A fluid distribution manifold comprising:
a first plate;
a second plate, at least a portion of at least the first plate and the second plate defining a relief pattern; and
a metal bonding agent disposed between the first plate and the second plate such that the first plate and the second plate form a fluid flow directing pattern defined by the relief pattern.

2. The manifold of claim 1, wherein the second plate includes a relief portion disposed opposite the relief portion of the first plate.

3. The manifold of claim 1, wherein the second plate includes a relief portion disposed offset from the relief portion of the first plate.

4. The manifold of claim 1, wherein the flow directing pattern defined by the relief pattern that remains free of the metal bonding agent.

5. The manifold of claim 1, the first plate including an output face, the output face including a finish that is polished prior to being bonded to the second plate.

6. A method of assembling a fluid distribution head comprising:
providing a first plate;
providing a second plate, at least a portion of at least the first plate and the second plate defining a relief pattern;
providing a metal bonding agent disposed between the first plate and the second plate; and
forming a fluid flow directing pattern defined by the relief pattern by bonding the first plate and the second plate together using the metal bonding agent.

7. The method of claim 6, wherein in providing a metal bonding agent disposed between the first plate and the second plate comprises:
providing a layer of metal bonding agent on one of the first plate and the second plate;
applying a mask over the layer of metal bonding agent; and
etching the layer of metal bonding agent and either the first plate or the second plate using the same mask.

8. The method of claim 7, wherein etching the layer of metal bonding agent and either the first plate or the second plate using the same mask includes etching the layer of metal bonding agent and either the first plate or the second plate in the same process step.

9. The method of claim 7, wherein etching the layer of metal bonding agent and either the first plate or the second plate using the same mask includes etching the layer of metal bonding agent and either the first plate or the second plate in separate process steps.

10. A method of depositing a thin film material on a substrate comprising:
providing a substrate;
providing a fluid distribution manifold including:
a first plate;
a second plate, at least a portion of at least the first plate and the second plate defining a relief pattern; and
a metal bonding agent disposed between the first plate and the second plate such that the first plate and the second plate form a fluid flow directing pattern defined by the relief pattern; and
causing a gaseous material to flow from the fluid distribution manifold toward the substrate after causing the gaseous material to flow through the fluid flow directing pattern defined by the relief pattern.
